(19) United States
(12) Patent Application Publication
(10) Pub. No.: US 2005/0000446 A1
(43) Pub. Date: Jan. 6, 2005

(54) Plasma processing apparatus and plasma processing method

(76) Inventors: Yukihiko Nakata, Yokohama-shi (JP); Tetsuya Ide, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/876,550

(22) Filed: Jun. 28, 2004

(30) Foreign Application Priority Data
Jul. 4, 2003 (JP) 2003-271007

(51) Int. Cl. C23C 16/00

(52) U.S. Cl. 118/723 MW

(57) ABSTRACT

A plasma processing apparatus includes at least one electromagnetic wave source for generating an electromagnetic wave, an electromagnetic wave-distributing waveguide portion for distributing the electromagnetic wave generated from the electromagnetic wave source, a plurality of waveguides each coupled with the electromagnetic wave-distributing waveguide portion, the waveguides being provided on the same plane, a plurality of slots provided in each of the waveguides, at least one electromagnetic wave radiating window provided to face each slot, and a vacuum vessel in which a plasma is generated by the electromagnetic wave radiated from the electromagnetic wave radiating window. The electromagnetic wave-distributing waveguide portion is provided on the plural waveguides.

### CROSS-REFERENCE TO RELATED APPLICATIONS

This application is based upon and claims the benefit of priority from prior Japanese Patent Application No. 2003-271007, filed Jul. 4, 2003, the entire contents of which are incorporated herein by reference.

### BACKGROUND OF THE INVENTION

1. Field of the Invention

The present invention relates to a plasma processing apparatus and a plasma processing method, particularly, to a plasma processing apparatus and a plasma processing method suitable for employment for application of a plasma processing to a large angular substrate.

2. Description of the Related Art

It is known to the art that a parallel plate type high frequency plasma processing apparatus or an electron cyclotron resonance (ECR) plasma processing apparatus is used for application of a plasma processing such as a film deposition, a surface modification or an etching in the manufacturing process of, for example, a semiconductor device or a liquid crystal display device.

In the parallel plate type plasma processing apparatus, the plasma density is low, and the electron temperature is high. Also, a DC magnetic field is required for the plasma excitation in the ECR plasma processing apparatus so as to give rise to the problem that it is difficult to apply a plasma processing to a large area.

Proposed in recent years is a plasma processing apparatus which does not require a magnetic field for the plasma excitation and which generates a plasma having a high density and a low electron temperature. A plasma processing apparatus of this particular type will now be described.

A first example of the known plasma processing apparatus is disclosed in, for example, Japanese Patent Disclosure (Kokai) No. 9-63793. In the plasma processing apparatus disclosed in this prior art, two slots collectively constituting a waveguide antenna are formed on the H plane, i.e., a plane perpendicular to the direction of the electric field of the microwave, of a rectangular waveguide, and a microwave power is supplied from these two slots into a vacuum vessel through an electromagnetic radiation window so as to generate a plasma within the vacuum vessel. The shape of each slot is changed stepwise or tapered such that the width of each slot is diminished toward the reflecting surface of the rectangular waveguide.

In recent years, the plasma processing apparatus used for manufacturing a semiconductor device or a liquid crystal display device is being rendered bulky with increase in the substrate size. Particularly, in the manufacture of a liquid crystal display device, it is necessary to use an apparatus capable of processing a large substrate having a size of about one meter square. The substrate sized at one meter square has an area about 10 times as large as that of the substrate having a diameter of 300 mm, which is used for the manufacture of a semiconductor device.

The raw material gases utilized in the plasma processing referred to above include, for example, reactive gases such as a monosilane gas, an oxygen gas, a hydrogen gas and a chlorine gas. A large amount of negative ions such as O⁻, H⁻, and Cl⁻ are present in the plasma of these gases. Naturally, required are manufacturing facilities and manufacturing method with the behavior of these negative ions taken into consideration.

A second example of the known plasma processing apparatus is disclosed in, for example, Japanese Patent Disclosure No. 2001-192840.

In the plasma processing apparatus disclosed in this prior art, an electromagnetic wave is distributed from an upper portion through two first waveguides into a plurality of second waveguides each having a slot and, then, introduced into a vacuum vessel through a plurality of electromagnetic wave radiation windows each formed of a dielectric material, the electro-magnetic wave radiation windows being arranged to correspond to the plural second waveguides. As a result, a plasma is generated within the vacuum vessel.

A third example of the known plasma processing apparatus is disclosed in, for example, Japanese Patent Disclosure No. 9-181052. In the plasma processing apparatus disclosed in this prior art, an electro-magnetic wave is distributed through a upper waveguide into a plurality of lower waveguides formed by a plurality of partition walls. Further, the electro-magnetic wave is guided from the slot formed in the lower waveguide into a vacuum vessel through a electromagnetic wave radiation window so as to generate a plasma within the vacuum vessel.

Each of the known plasma processing apparatuses pointed out above gives rise to a serious problem as pointed out below.

Specifically, in the first example of the plasma processing apparatus noted above, in which the microwave transmitted through a rectangular waveguide is emitted from the two slots, the ambipolar diffusion coefficient of the plasma is diminished in the case where the formed plasma is a reactive plasma containing a large amount of negative ions. This gives rise to the problem that the plasma tends to be concentrated in the vicinity of the slot through which the microwave is emitted. The difficulty is rendered more serious in the case where the plasma pressure is high. It follows that it is difficult to use the plasma processing apparatus of the particular construction for application of a plasma processing using as the raw material the gases easily forming a negative ion such as an oxygen gas, a hydrogen gas and a chlorine gas to a substrate having a large area. Particularly, the plasma processing is rendered more difficult in the case where the plasma pressure is high. Further, in the plasma processing apparatus of the particular type, the slots forming the waveguide antenna are locally distributed relative to that surface of the substrate which is to be subjected to the plasma processing. It follows that the plasma density within the vacuum vessel tends to be rendered nonuniform.

In the second example of the known plasma processing apparatus referred above, the electro-magnetic wave is supplied from an upper portion into the vacuum vessel through a plurality of waveguide systems including a plurality of first waveguides and a plurality of second waveguides. As a result, various problems remain unsolved. For example, the waveguide systems are rendered complex, the volume occupied by the apparatus is increased, and the apparatus cost is increased.

Further, in the third example of the known plasma processing apparatus noted above, the second waveguides are rendered different from each other in length so as to form a circular configuration corresponding to the circular substrate. As a result, it is difficult to supply an electromagnetic wave uniformly from the first waveguide into each of the second waveguides. Also, the plasma processing apparatus of this type is constructed to apply a plasma processing to a circular substrate and, thus, is not suitable sufficiently for application of a plasma processing to an angular substrate. Further, in the plasma processing apparatus of this type, the upper waveguide and the lower waveguide are allowed to communicate with each other without using a directional coupler in each coupling section. It follows that, in the plasma processing apparatus of this type, it is difficult to distribute uniformly the electromagnetic wave from the upper waveguide into the lower waveguide.

### BRIEF SUMMARY OF THE INVENTION

According to a first aspect of the present invention, which is intended to achieve the object noted above, there is provided a plasma processing apparatus, comprising at least one electromagnetic wave source for generating an electromagnetic wave, an electromagnetic wave-distributing waveguide portion for distributing the electromagnetic wave generated from the electromagnetic wave source, a plurality of waveguides provided on a single plane, each waveguide being coupled with the electromagnetic wave-distributing waveguide portion, each waveguide being coupled with the electromagnetic wave-distributing waveguide portion, a plurality of slots provided in each of the waveguides, at least one electromagnetic wave radiating window provided to face each slot, and a vacuum vessel in which a plasma is generated by the electromagnetic wave radiated from the electromagnetic wave radiating window, wherein the electromagnetic wave-distributing waveguide portion is provided on the plural waveguides.

A large power can be supplied into the plasma processing apparatus of the particular construction described above so as to make it possible to process an angular substrate having a large area with a plasma having a high uniformity. In addition, the plasma processing apparatus according to the first aspect of the present invention is simple in construction.

According to a second aspect of the present invention, there is provided a plasma processing apparatus, comprising at least one electromagnetic wave source for generating an electromagnetic wave, an electromagnetic wave-distributing waveguide portion for distributing the electromagnetic wave generated from the electromagnetic wave source, a plurality of waveguides each having an electric field plane and a magnetic field plane perpendicular to the electric field plane and provided on the same plane, a plurality of slots provided in each of the waveguide, at least one electromagnetic wave radiating window provided to face each slot, and a vacuum vessel in which a plasma is generated by the electromagnetic wave radiated from the electromagnetic wave radiating window, wherein the plural waveguides are equal to each other in the length in the propagating direction of the electromagnetic wave, and the electromagnetic wave-distributing waveguide portion is provided on the plural waveguides and coupled with each of the waveguides in the magnetic field plane of the waveguide.

A large power can be supplied into the plasma processing apparatus of the particular construction described above so as to make it possible to process an angular substrate having a large area with a plasma having a high uniformity. In addition, the plasma processing apparatus according to the second aspect of the present invention is simple in construction.

According to a third aspect of the present invention, there is provided a plasma processing apparatus, comprising at least one electromagnetic wave source for generating an electromagnetic wave, an electromagnetic wave-distributing waveguide portion for distributing the electromagnetic wave generated from the electromagnetic wave source, a plurality of waveguides coupled with the electromagnetic wave-distributing waveguide portion and provided in parallel on the same plane, a plurality of slots provided in each of the plural waveguides, at least one electromagnetic wave radiating window provided to face each slot, and a vacuum vessel in which a plasma is generated by the electromagnetic wave radiated from the electromagnetic wave radiating window, wherein the plural waveguides are equal to each other in the length in the propagating direction of the electromagnetic wave, and the electromagnetic wave-distributing waveguide portion is provided on the plural waveguides in a manner to cross each of the waveguides at right angles.

A large power can be supplied into the plasma processing apparatus of the particular construction described above so as to make it possible to process an angular substrate having a large area with a plasma having a high uniformity. In addition, the plasma processing apparatus according to the third aspect of the present invention is simple in construction.

According to a fourth aspect of the present invention, there is provided a plasma processing apparatus, comprising at least one electromagnetic wave source for generating an electromagnetic wave, an electromagnetic wave-distributing waveguide portion for distributing the electromagnetic wave generated from the electromagnetic wave source, a plurality of waveguides each coupled with the electromagnetic wave-distributing waveguide portion, the waveguides being formed on the same plane, a plurality of slots provided in each of the waveguides, at least one electromagnetic wave radiating window provided to face each slot, and a vacuum vessel in which a plasma is generated by the electromagnetic wave radiated from the electromagnetic wave radiating window, wherein the electromagnetic wave-distributing waveguide portion is provided on the plural waveguides and is coupled with each of the waveguides with a cross-guide coupler interposed therebetween.

A large power can be supplied into the plasma processing apparatus of the particular construction described above so as to make it possible to process the substrate having a large area with a plasma having a high uniformity. In addition, the plasma processing apparatus according to the fourth aspect of the present invention is simple in construction. Further, since the electromagnetic wave-distributing waveguide portion is coupled with each waveguide with a cross-guide coupler interposed therebetween, it is possible to permit the electromagnetic wave distributed to each waveguide to be propagated in one direction.

According to a fifth aspect of the present invention, there is provided a plasma processing apparatus, comprising at least one electromagnetic wave source for generating an electromagnetic wave, an electromagnetic wave-distributing waveguide portion for distributing the electromagnetic wave generated from the electromagnetic wave source, a plurality of waveguides each coupled with the electromagnetic wave-distributing waveguide portion, the waveguides being formed on the same plane, a plurality of slots provided in each of the waveguides, at least one electromagnetic wave radiating window provided to face each slot, and a vacuum vessel in which a plasma is generated by the electromagnetic wave radiated from the electromagnetic wave radiating window, wherein the electromagnetic wave-distributing waveguide portion is provided on the plural waveguides, and an electromagnetic wave absorber is arranged in an edge portion of each waveguide in a direction opposite to the propagating direction of the electromagnetic wave.

A large power can be supplied into the plasma processing apparatus of the particular construction described above so as to make it possible to process an angular substrate having a large area with a plasma having a high uniformity. In addition, the plasma processing apparatus according to the fifth aspect of the present invention is simple in construction. Further, since an electromagnetic wave absorber is arranged in the edge portion of each waveguide in a direction opposite to the electromagnetic wave propagating direction, it is possible to permit the electromagnetic wave distributed to each waveguide to be propagated in one direction.

According to a sixth aspect of the present invention, there is provided a plasma processing apparatus, comprising at least one electromagnetic wave source for generating an electromagnetic wave, an electromagnetic wave-distributing waveguide portion for distributing the electromagnetic wave generated from the electromagnetic wave source, a plurality of waveguides each coupled with the electromagnetic wave-distributing waveguide portion and provided in parallel on the same plane, the waveguides being provided on the same plane, a plurality of slots provided in each of the plural waveguides, at least one electromagnetic wave radiating window provided to face each slot, and a vacuum vessel in which a plasma is generated by the electromagnetic wave radiated from the electromagnetic wave radiating window, wherein the electromagnetic wave-distributing waveguide portion is provided on the plural waveguides, and the distance between the inner surfaces of the adjacent waveguides is set shorter than the distance between the mutually facing inner surfaces of the waveguide, the inner surfaces extending in parallel.

A large power can be supplied into the plasma processing apparatus of the particular construction described above so as to make it possible to process an angular substrate having a large area with a plasma having a high uniformity. In addition, the plasma processing apparatus according to the sixth aspect of the present invention is simple in construction. Further, since the distance between the inner surfaces of the adjacent waveguides is set shorter than the distance between the mutually facing inner surfaces of the waveguide, the inner surfaces extending in parallel, it is possible to provide a plasma processing apparatus having a small footprint and having a uniform plasma density.

As described above, it is possible for the electromagnetic wave-distributing waveguide portion to be coupled with each waveguide with a cross-guide coupler interposed therebetween. Also, it is possible to arrange an electromagnetic wave absorber in an edge portion of the waveguide in a direction opposite to the propagating direction of the electromagnetic wave. It is also possible to permit the electromagnetic wave-distributing waveguide portion to be coupled with the waveguide in a circular coupling hole formed in the overlapping portion between the electromagnetic wave-distributing waveguide portion and the waveguide. Further, it is also possible to permit the electromagnetic wave-distributing waveguide portion to be coupled with the waveguides in oblong coupling holes inclined in alternately opposite directions relative to the extending direction of the electromagnetic wave-distributing waveguide portion.

The particular constructions described above make it possible to permit the electromagnetic wave distributed to each waveguide to be propagated in one direction.

Where the electromagnetic wave-distributing waveguide portion is coupled with the waveguides in the oblong coupling holes, it is desirable for the oblong coupling holes to be inclined in alternately opposite directions by ±45° relative to the extending direction of the electromagnetic wave-distributing waveguide portion.

The construction described above permits distributing the electromagnetic wave to each of the waveguides satisfactorily. In addition, the electromagnetic wave distributed to each waveguide can be propagated in one direction.

It is possible for each of the waveguides to be branched in two opposite directions from the electromagnetic wave-distributing waveguide portion.

The particular construction described above makes it possible to provide a plasma processing apparatus, which permits processing a substrate having a large surface area, which is small in its footprint, and which permits forming a plasma having a uniform plasma density.

It is desirable for the plasma processing apparatus of the present invention to be constructed to permit the electromagnetic wave to be distributed from the electromagnetic wave-distributing waveguide portion to each of the waveguides such that the same amount of the power of the electromagnetic wave is supplied to each of the waveguides. In this case, the electro-magnetic wave can be radiated uniformly within the vacuum vessel, with the result that a uniform plasma can be formed within the vacuum vessel.

It is desirable for the slots provided in the waveguides to be distributed uniformly such that the electromagnetic wave is supplied uniformly into the vacuum vessel over the entire region of the substrate to which the plasma processing is applied. In this case, it is possible to apply a plasma processing to the substrate having a large surface area with a uniform plasma density.

It is desirable to arrange a plurality of electromagnetic wave radiating windows within the vacuum vessel such that each electromagnetic wave radiating window is positioned to face at least two slots. In this case, it is desirable to maintain a vacuum state between the electromagnetic wave radiating windows and the vacuum vessel.

The particular construction of the present invention described above permits decreasing the processing cost of, for example, the wall such as a ceiling plate of the vacuum vessel. Also, in the case of arranging a plurality of electromagnetic wave radiation windows, it is possible to decrease the thickness of the individual electromagnetic wave radiating window. It follows that the substrate having a large surface area can be processed with a plasma having a uniform plasma density.

It is desirable for the electromagnetic wave radiating window to be supported by at least one beam arranged within the vacuum vessel. In this case, it is desirable for the inner surface of the beam to be covered with a dielectric material.

Where the inner surface of the beam is covered with a dielectric material, the electromagnetic wave can be expanded within the vacuum vessel. It follows that it is possible to form a plasma having a high uniformity within the vacuum vessel, compared with the case where the inner surface of the beam is not covered with the dielectric material.

In the case of using a plurality of electro-magnetic wave sources, it is desirable for the adjacent electromagnetic wave sources to differ from each other in the frequency.

The maximum output of a single electromagnetic wave source is limited. However, a large power can be utilized by using a plurality of electromagnetic wave sources. It should also be noted that, in the case of using a plurality of electromagnetic wave sources such as microwave sources, an interference takes place between the formed plasmas. However, the interference between the formed plasmas can be suppressed by allowing the adjacent electromagnetic wave sources to differ from each other in the frequency.

It is desirable for the frequency of the electromagnetic wave source to be set at 2.45 GHz. The standard frequency of the electromagnetic wave source (microwave source) is set nowadays at 2.45 GHz. Naturally, the electromagnetic wave source generating an electromagnetic radiation window having a frequency of 2.45 GHz is cheap, and various kinds of electro-magnetic wave sources are available in the case where the frequency of the generated electromagnetic wave is set at 2.45 GHz.

At least one of a plasma oxidation, a plasma film-formation and a plasma etching can be performed as the plasma processing that is carried out within the vacuum vessel. In other words, at least one of a plasma oxidation, a plasma film-formation and a plasma etching can be performed by using the plasma processing apparatus of the present invention having a small footprint and capable of forming a plasma having a uniform plasma density.

According to an eight aspect of the present invention, there is provided a plasma processing method, which permits performing a plasma oxidation and a plasma film-formation under a vacuum state by using the plasma processing apparatus of the construction described above, wherein the plasma oxidation and the plasma film-formation are carried out consecutively without breaking the vacuum stated within the vacuum vessel.

The plasma generated by using the plasma processing apparatus of the construction described above has a high electron density. In addition, the electron temperatures are low and highly uniform. The plasma processing method according to the eighth aspect of the present invention makes it possible to perform very good plasma oxidation and plasma film-formation. In addition, the plasma oxidation and the plasma film-formation can be performed consecutively without breaking the vacuum state within the vacuum vessel. It follows that it is possible to form a film substantially free from contamination under the state that the plasma density is uniform.

Further, according to a ninth aspect of the present invention, there is provided a plasma processing method, in which at least one of a plasma oxidation, a plasma film-formation and a plasma etching is carried out by using the plasma processing apparatus of the construction described above.

The plasma generated by using the plasma processing apparatus of the construction described above has a high electron density. In addition, the electron temperatures are low and highly uniform. It follows that the plasma processing method according to the ninth aspect of the present invention makes it possible to perform at least one plasma processing selected from the group consisting of very good plasma oxidation, plasma film-formation, and plasma etching.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the embodiments given below, serve to explain the principles of the invention.

FIG. 1A is a cross sectional view schematically showing the construction of a plasma processing apparatus according to a first embodiment of the present invention;

FIG. 1B is an upper view showing the construction of the plasma processing apparatus shown in FIG. 1A;

FIG. 1C is a cross sectional view showing the construction of the plasma processing apparatus along the line 1C-1C shown in FIG. 1B for clearly setting forth the propagating direction of the electromagnetic wave;

FIG. 1D shows the propagating direction and the rotating direction of the circular polarization of the electromagnetic wave utilized in the plasma processing apparatus shown in FIG. 1A;

FIG. 1E is a cross sectional view showing the construction of that region of the plasma processing apparatus shown in FIG. 1A which is positioned in the vicinity of the electromagnetic wave radiating window;

FIG. 1F is a cross sectional view showing the construction of that region of another plasma processing apparatus according to the first embodiment of the present invention which is positioned in the vicinity of the electromagnetic wave radiating window;

FIG. 1G is a side view showing the inner structure of the microwave source included in the plasma processing apparatus shown in FIG. 1A;

FIGS. 1H and 1I collectively show the construction of a cross-guide coupler;

FIG. 1J shows the propagating direction and the rotating direction of the circular polarization of the electromagnetic wave in the vicinity of the cross-guide coupler included in the plasma processing apparatus shown in FIG. 1A;

FIG. 2A is a cross sectional view schematically showing the construction of a plasma processing apparatus according to a second embodiment of the present invention;

FIG. 2B is an upper view of the plasma processing apparatus shown in FIG. 2A;

FIG. 3A is a cross sectional view schematically showing the construction of a plasma processing apparatus according to a third embodiment of the present invention;

FIG. 3B is an upper view of the plasma processing apparatus shown in FIG. 3A;

FIG. 4A is a cross sectional view schematically showing the construction of a plasma processing apparatus according to a fourth embodiment of the present invention;

FIG. 4B is an upper view of the plasma processing apparatus shown in FIG. 4A;

FIG. 5 is an upper view showing the construction of a plasma processing apparatus according to a fifth embodiment of the present invention;

FIG. 6A is a cross sectional view schematically showing the construction of a plasma processing apparatus according to a sixth embodiment of the present invention;

FIG. 6B is an upper view of the plasma processing apparatus shown in FIG. 6A;

FIG. 7 is an upper view showing the construction of a plasma processing apparatus according to a seventh embodiment of the present invention;

FIGS. 8A, 8B and 8C are flow charts collectively showing the process of forming n-channel and p-channel polycrystalline silicon thin film transistors included in a liquid crystal display device, the process being performed by the plasma processing method according to an eighth embodiment of the present invention; and

FIGS. 9A to 9E cross sectional views collectively showing the process of forming a polycrystalline silicon thin film transistor by the plasma processing method according to the eighth embodiment of the present invention.

### DETAILED DESCRIPTION OF THE INVENTION

Some embodiments of the present invention will now be described in detail with reference to the accompanying drawings. Throughout the accompanying drawings, the members of the apparatus performing the same function are denoted by the same reference numerals so as to avoid the overlapping description.

### FIRST EMBODIMENT

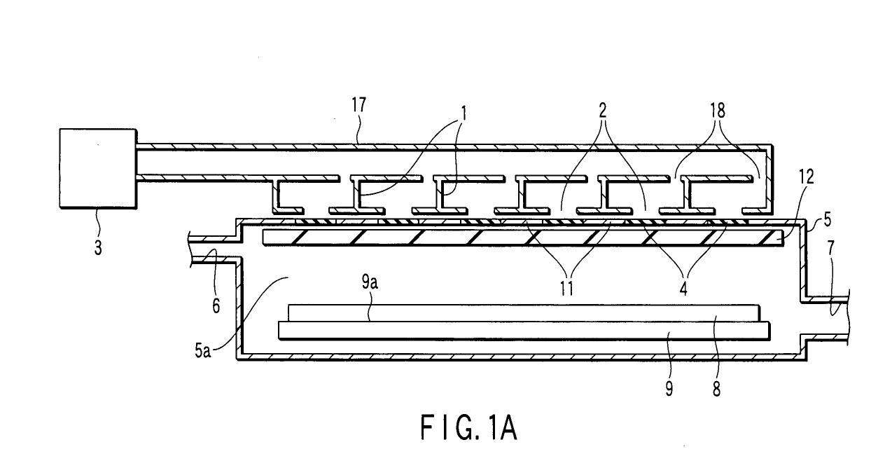

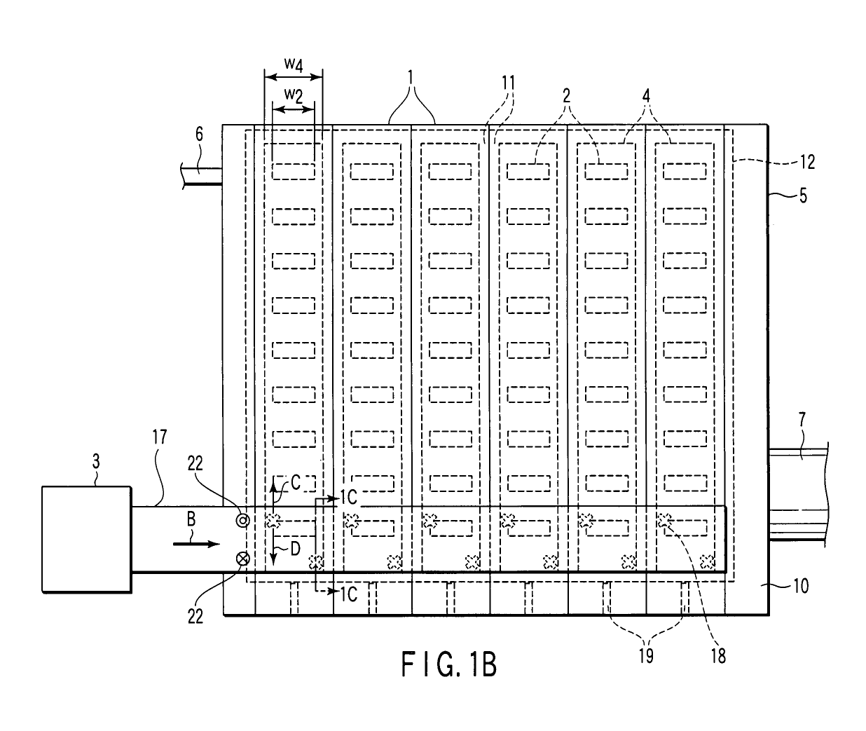

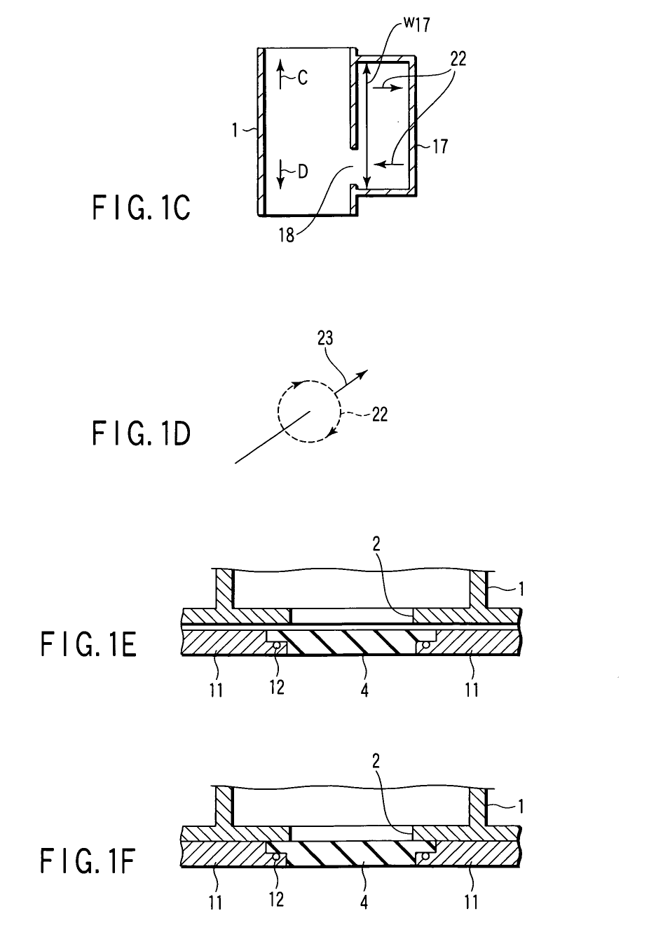

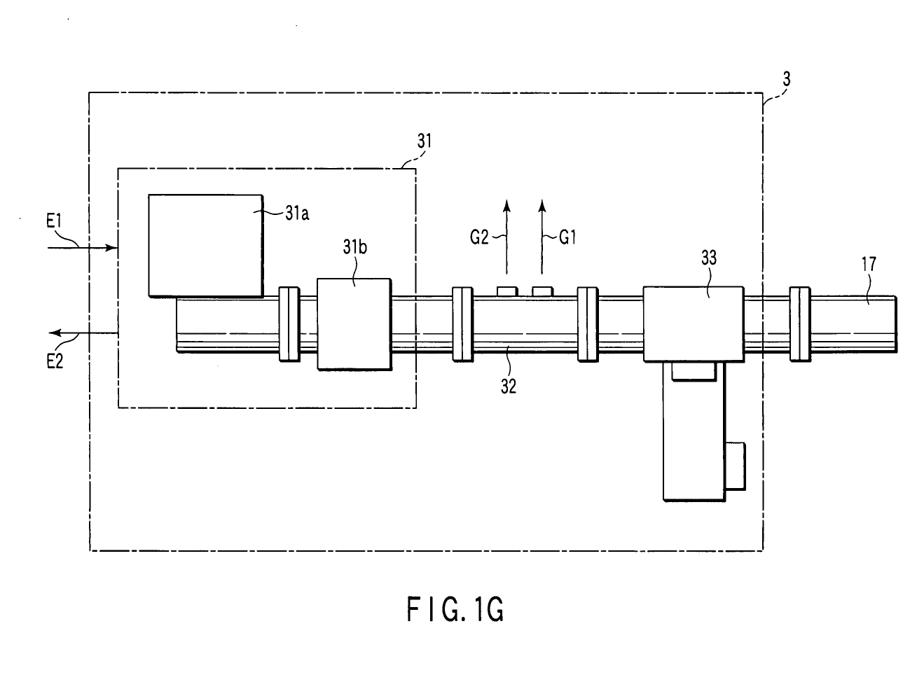

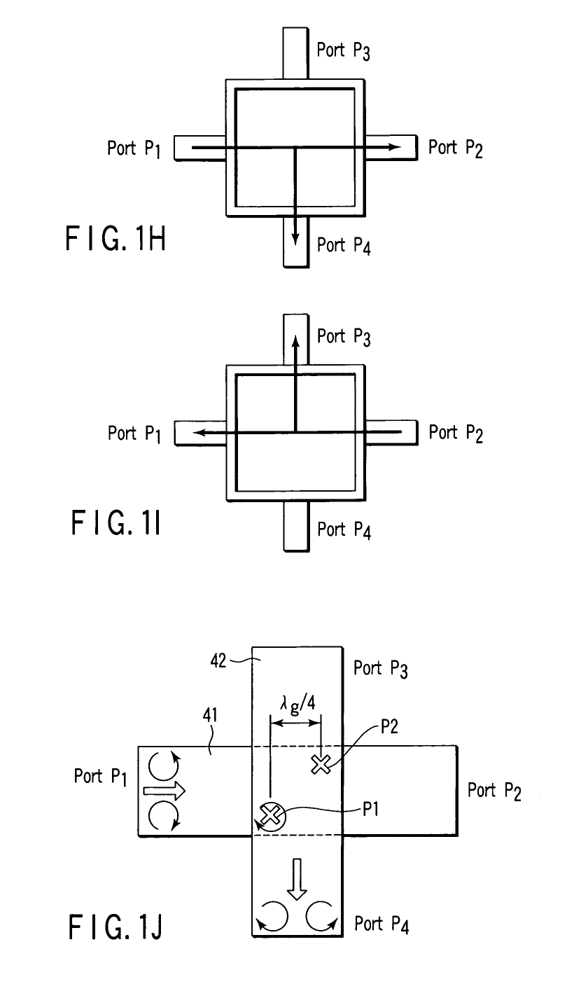

FIG. 1A is a cross sectional view schematically showing the construction of a plasma processing apparatus according to a first embodiment of the present invention. FIG. 1B is an upper view of the plasma processing apparatus shown in FIG. 1A. FIG. 1C is a cross sectional view along the line 1C-1C shown in FIG. 1B. A waveguide portion for distributing the electromagnetic wave and a waveguide are partly shown in a magnified fashion in FIG. 1C. Further, FIG. 1D schematically shows the propagating direction and the rotating direction of the circular polarization of the electromagnetic wave utilized in the plasma processing apparatus shown in FIG. 1A.

A reference numeral 1 shown in the drawing denotes a plurality of waveguides for radiating an electro-magnetic wave to a vacuum vessel 5 referred to herein later. For example, a rectangular waveguide, i.e., a waveguide having a rectangular cross section, can be used as the waveguide 1. These waveguides 1 are formed to have the same shape and arranged in parallel on the same plane under the state that the both ends of the waveguides 1 are aligned. A reference numeral 2 denotes a plurality of slots each constituting a waveguide antenna. A plurality of slots 2 are provided in each waveguide 1. A reference numeral 3 denotes a microwave source, i.e., an electromagnetic wave source, generating a microwave having a frequency of, for example, 2.45 GHz. A reference numeral 4 denotes at least one electromagnetic wave radiating window (electromagnetic wave introducing window) made of a dielectric material such as quartz, glass or a ceramic material. For example, a plurality of electromagnetic wave radiating windows are formed in the plasma processing apparatus of the present invention. Each electromagnetic wave radiating window 4 is provided to face the waveguide 1. To be more specific, the electromagnetic wave radiating windows 4 are arranged to face the plural slots 2 formed in the waveguide 1. The reference numeral 5 referred to previously denotes the vacuum vessel referred to previously. A process chamber 5a for generating a plasma by exciting a process gas with the electromagnetic wave is formed inside the vacuum vessel 5. The electromagnetic wave radiating window 4 constitutes a part of the wall defining the vacuum vessel 5. A reference numeral 6 denotes a gas inlet port for supplying a process gas into the process chamber 5a formed inside the vacuum vessel 5. A reference numeral 7 denotes a gas outlet port for discharging the waste gas from within the process chamber 5a formed inside the vacuum vessel 5. In other words, the gas inlet port 6 for introducing a process gas (raw material gas) and the gas outlet port 7 for discharging the introduced gas are connected to the vacuum vessel 5. A reference numeral 8 denotes a substrate that is to be subjected to the plasma processing. A reference numeral 9 denotes a substrate table for supporting the substrate 8 to be processed. The substrate table 9 includes a supporting surface 9a capable of supporting the substrate 8 to be processed. The supporting surface 9a of the substrate table 9 is positioned to face the electromagnetic wave radiating windows 4 and includes a process region that is to be subjected to the plasma processing. The slots 2 are uniformly distributed such that the electromagnetic wave is uniformly introduced into the process chamber 5a in a manner to cover the entire process region included in the supporting surface 9a of the substrate table 9. A reference numeral 11 denotes at least one beam for supporting the electromagnetic wave radiating windows 4. For example, a plurality of beams 11 are included in the plasma processing apparatus of the present invention. The beams 11 constitute a part of the wall defining the vacuum vessel 5. A vacuum state is maintained in the clearance between the electro-magnetic wave radiating windows 4 and the wall of the vacuum vessel 5, i.e., in the clearance between the electromagnetic wave radiating windows 4 and the beams 11. Further, a reference numeral 17 denotes a waveguide portion for distributing the electromagnetic wave (microwave) generated from the microwave source 3 into each of the rectangular waveguides 1. The electromagnetic wave-distributing waveguide portion 17 is formed above the plural rectangular waveguides 1 in a manner to extend over the waveguides 1.

As shown in FIG. 1G, the microwave source 3 includes an oscillating section 31, a power monitor 32, and an E-H tuner 33 acting as a matching device. The oscillating section 31 includes a magnetron 31a acting as an oscillator and an isolator 31b. The isolator 31b serves to protect the magnetron 31a from the reflected wave. The oscillating section 31 is cooled by a liquid-cooling type cooling device (not shown). Incidentally, arrows E1 and E2 shown in FIG. 1G denote the flow of the cooling water. The power monitor 32 is for monitoring the propagating wave and the reflected wave. On the other hand, an arrow G1 shown in FIG. 1G denotes the propagating direction of the propagating wave, and another arrow G2 denotes the propagating direction of the reflected wave. Further, the E-H tuner 33 serves to lower the reflected wave.

The waveguides 1 are provided side by side above the vacuum vessel 5 and extend on a horizontal plane in a direction perpendicular to the extending direction of the electromagnetic wave-distributing waveguide portion 17. It follows that the both side surfaces of the waveguide 1 form an electric field plane (E-plane), and the upper and lower surfaces of the waveguide 1 form a magnetic field plane (H-plane). Each of the waveguides 1 is coupled with the electromagnetic wave-distributing waveguide portion 17 in its upper surface, i.e., in the magnetic field plane (H-plane), which is perpendicular to the electric field plane (E-plane). In the first embodiment of the present invention, the electro-magnetic wave-distributing waveguide portion 17 is also arranged on a horizontal plane and extends in a direction perpendicular to the extending direction of each of the waveguides 1. It follows that the electro-magnetic wave-distributing waveguide portion 17 is coupled with each of the waveguides 1 in the magnetic field plane (H-plane) of the electromagnetic wave-distributing waveguide portion 17 and the magnetic field plane (H-plane) of each of the waveguides 1. It should be noted that the electromagnetic wave-distributing waveguide portion 17 is arranged in the edge portions on one side of the waveguides 1 and extends in a direction perpendicular to the extending direction of the waveguides 1.

Also, the electromagnetic wave-distributing waveguide portion 17, which extends in a direction perpendicular to the extending direction of the waveguides 1, is provided in a manner to overlap with the waveguides 1 and allowed to be coupled with each of the waveguides 1 by a coupling hole section 18. To be more specific, the electromagnetic wave-distributing waveguide portion 17, a single waveguide 1, and a single coupling hole section 18 collectively form a single directional coupler. The particular directional coupler is formed in each of the coupling portions between the electromagnetic wave-distributing waveguide portion 17 and the waveguides 1. These directional couplers are capable of taking out partly the electro-magnetic wave propagating in one direction along the electromagnetic wave-distributing waveguide portion 17 so as to permit the part of the electromagnetic wave thus taken out to be introduced into each of the waveguides 1. The electromagnetic wave introduced into the waveguide 1 is propagated in one direction. The first embodiment of the present invention is directed to the case where the electromagnetic wave-distributing waveguide portion 17 extends in a direction perpendicular to the extending direction of the waveguide 1, and the coupling hole section 18 is formed of, for example, two cross-shaped (+) holes. The particular construction is known to the art as the cross-guide coupler.

As shown in FIG. 1B, if the electromagnetic wave is propagated in a direction denoted by an arrow B, i.e., propagated from the left side toward the right side in FIG. 1B, a circular polarization of the magnetic field is generated in a position substantially λ/4 away from the inner surface of the tube wall of the electromagnetic wave-distributing waveguide portion 17 in the base mode (TE₁₀) of the rectangular waveguide. Incidentally, λis equal to the width (distance) w₁₇ shown in FIG. 1C, i.e., the larger distance between the mutually facing inner side surfaces, which extend in parallel, of the electro-magnetic wave-distributing waveguide portion 17. Incidentally, a reference numeral 22 shown in each of FIGS. 1B, 1C and 1D denotes the rotating direction of the circular polarization. Also, a reference numeral 3 shown in FIG., 1D denotes the propagating direction of circular polarization.

As shown in FIG. 1B and FIG. 1C, which shows the cross section along the line 1C-1C shown in FIG. 1B, a relationship of a right-hand screw is formed between the rotating direction 22 of the circular polarization and the propagating direction of the circular polarization. In FIG. 1D, the propagating direction of the circular polarization is schematically denoted by an arrow extending obliquely upward and rightward. However, the actual propagating direction of the circular polarization is perpendicular to the paper. Since the electromagnetic wave propagated in the direction denoted by the arrow B within the electro-magnetic wave-distributing waveguide portion 17 is transmitted into each of the waveguides 1 through the coupling hole sections 18, the circular polarization described above is also generated in each of the waveguides 1. It follows that the electromagnetic wave, i.e., the microwave in this embodiment, is propagated within each of the waveguides 1 in a direction denoted by an arrow C, i.e., from the lower side toward the upper side in FIGS. 1B and 1C. However, the electromagnetic wave is not propagated in a direction denoted by an arrow D, i.e., from the upper side toward the lower side in FIGS. 1B and 1C. What should be notes is that, where the electromagnetic wave-distributing waveguide portion 17 extends in a direction perpendicular to the extending direction of each of the waveguides 1, the use of the cross-guide coupler permits the electromagnetic wave to be distributed from the electromagnetic wave-distributing waveguide portion 17 to each of the waveguides 1 and also permits the electromagnetic wave distributed to each waveguide 1 to be propagated in one direction. In other words, the microwave oscillated from the oscillator 31a included in the microwave source 3 is propagated within the electromagnetic wave-distributing waveguide portion 17 and distributed by the coupling hole section 18 into the waveguide 1. The microwave is, then, transferred within the waveguide 1 so as to be radiated from the slot 2 constituting the waveguide antenna into the vacuum vessel 5 through the electromagnetic wave radiating window 4.

A supplemental explanation of the directional coupler will now be given below briefly. As shown in FIGS. 1H, the microwave incident on the directional coupler through a port P₁ is transmitted into a port P₂ and a port P₄ at a prescribed ratio, but is not transmitted into a port P₃. Also, the microwave incident on the directional coupler trough the port P₂ is transmitted into the port P₁ and the port P₃, but is not transmitted into the port P₄, as shown in FIG. 1I.

As shown in FIG. 1J, the cross-guide coupler is constructed such that a lower rectangular waveguide 41 having the port P₁ and the port P₂ extends to cross at right angles an upper rectangular waveguide 42 having the port P₃ and the port P₄. Where the lower rectangular waveguide 41 extends to cross the upper rectangular waveguide 42 at right angles, it is possible to obtain the effect of lowering the electric field coupling and improving the directivity, if the lower and upper rectangular waveguides 41 and 42 are coupled with each other by a cross-shaped hole. In this case, the transmitting direction of the electromagnetic wave is determined in the portion of the cross-shaped hole.

In the basic mode of the rectangular waveguide having a rectangular cross section, a circular polarization of the magnetic field is generated in a position close to the side surface (E-plane), as shown in FIG. 1J. It follows that the circular polarization having the magnetic field of the same direction is generated in each of the lower rectangular waveguide 41 and the upper rectangular waveguide 42 in the portion of the cross-shaped hole. Since the direction of the circular polarization determines the transmitting direction of the electromagnetic wave, the cross-shaped hole P1 permits the electromagnetic wave incident on the port P₁ to be transmitted only toward the port P₄.

Incidentally, a cross-guide coupler can be constructed by forming the cross-shaped hole P1. It is possible to increase the coupling amount, if a cross-shaped hole P2 is formed in the coupling portion, i.e., the overlapping portion between the lower rectangular waveguide 41 and the upper rectangular waveguide 42, such that the cross-shaped hole P2 is positioned diagonal to the cross-shaped hole P1. It is desirable for the cross-shaped hole P1 and the cross-shaped hole P2 to be positioned such that a distance of λg/⁴ is provided between the straight line passing through the cross-shaped hole P1 and parallel to the upper rectangular waveguide 42 and the straight line passing through the cross-shaped hole P2 and parallel to the upper rectangular waveguide 42, as shown in FIG. 1J. The symbol λ_{g} noted above, which is called a guide wavelength, can be represented by the formula given below:
λ_{g}=λ₀/(1−(λ₀/2w₁₇)²)^{0.5}
where w₁₇ denotes the longer distance between the mutually facing inner surfaces, which are parallel, of the electromagnetic wave-distributing waveguide portion 17 shown in FIG. 1C, and λ₀ denotes the wavelength of the electromagnetic wave transmitted through a free space.

The cross-guide coupler is designed to permit the electromagnetic wave of the same power to be distributed from the electromagnetic wave-distributing waveguide portion 17 to each of the waveguides 1. In other words, the electromagnetic wave generated from the microwave source 3 is distributed from the electromagnetic wave-distributing waveguide portion 17 to the plural waveguides 1 such that the electro-magnetic wave of the same power is distributed to each waveguide 1. In other words, the power of the electromagnetic wave is divided by the number N of waveguides 1 so as to supply 1/N power of the electromagnetic wave into each of the waveguides 1. It is advisable for the coupling hole section 18 to have at least one cross-shaped hole. Alternatively, it is also possible for the coupling hole section 18 to include at least one circular coupling hole or at least one oblong coupling hole. Also, the size of the slot 2 and the distance between the adjacent slots 2 are determined to permit the electromagnetic wave to be radiated uniformly from the slots 2 formed in each waveguide 1. Where the plasma processing apparatus is designed in this fashion, the electromagnetic wave can be radiated uniformly into the vacuum vessel 5 so as to form a highly uniform plasma within the process chamber 5a. Also, as shown in FIG. 1B, it is advisable to mount a no-reflection terminator 19 at the edge portion of each of the waveguides 1 on the side opposite to the tip in the propagating direction of the electromagnetic wave, i.e., at the edge portion on the side of the electromagnetic wave-distributing waveguide portion 17. In this case, it is possible to cope with, for example, the deviation in the size of the slot 2. In addition, the arrangement of the no-reflection terminator 19 produces the merit of improving the degree of freedom in the design of the apparatus.

The no-reflection terminator 19 is formed by arranging, for example, an electromagnetic wave absorber along the central line of the waveguide 1 in a direction parallel to the electric field plane of the electromagnetic wave. If the electromagnetic wave absorber is arranged, an eddy current flows on the surface of the electromagnetic wave absorber so as to increase the loss. As a result, the energy of the propagating electromagnetic wave can be attenuated. The edge portion of the electromagnetic wave absorber on the incident side of the electromagnetic wave, which is opposite to the distal end of the electromagnetic wave absorber, is inclined for the matching with the characteristic impedance of the waveguide 1. The electromagnetic wave absorber can be prepared by, for example, baking a carbon film to the surface of an insulator such as glass or porcelain.

Compared with the system called a single layer type, in which the electromagnetic wave-distributing waveguide portion 17 and a plurality of waveguides 1 are provided on the same plane, the multi-layer structure as in the first embodiment of the present invention, in which the electromagnetic wave-distributing waveguide portion 17 and a large number of waveguides 1 are superposed one upon the other, permits facilitating the design of the coupler and the slots 2 because the design criteria of the coupler including the cross-guide coupler are established in the multi-layer structure. As shown in FIGS. 1E and 1F, it is desirable for the clearance between the electro-magnetic wave radiating window 4 and the beam 11 to be held hermetic by using an O-ring 12. Also, the plasma processing apparatus can be employed for processing an angular substrate by allowing the waveguides 1 to be equal to each other in the length in the propagating direction of the electromagnetic wave. It is desirable to design the slots 2 so as to permit the directional coupler to radiate the electromagnetic wave distributed to each waveguide 1 uniformly into the vacuum vessel 5. If the plural waveguides 1 are formed substantially equal to each other in length as in the first embodiment of the present invention, it is also possible to obtain an effect that the design of the directional coupler and the slots 2 can be facilitated. Also, where a directional coupler is arranged, the apparatus can be designed easily by changing the degree of coupling, even if the plural waveguides 1 are not equal to each other in length.

The electromagnetic wave-distributing waveguide portion 17 is coupled with each of the waveguides 1 by the magnetic field plane (H-plane) of the electro-magnetic wave-distributing waveguide portion 17 and the magnetic field plane (H-plane) of each of the waveguides 1. Where the electromagnetic wave-distributing waveguide portion 17 and each of the waveguides 1 is formed of a waveguide having a rectangular cross section as in the first embodiment of the present invention, it is reasonable to state that the coupling is achieved on those surfaces of the electromagnetic wave-distributing waveguide portion 17 and the waveguides 1 which have a larger width in the cross section.

The width w₄ of the electromagnetic wave radiating window 4, which is shown in FIG. 1B, is set at, for example, about 10 cm, and the width w₂ of the slot 2 is set smaller than the width w₄ by several millimeters. If the width w₄ of the electromagnetic wave radiating window 4 is decreased by forming a plurality of electromagnetic wave radiating windows 4, it is possible to decrease the thickness of the electro-magnetic wave radiating window 4 so as to decrease the loss of the electromagnetic wave. Also, it is possible to provide a large plasma processing apparatus capable of coping with a large substrate.

Each of the waveguides 1 is provided above the vacuum vessel 5. Also, the electromagnetic wave-distributing waveguide portion 17 is arranged above the waveguides 1. The adjacent waveguides 1 are arranged close to each other on the same plane such that the distance between the inner surface of an optional waveguide 1 and the inner surface of the adjacent waveguide 1 is smaller than the distance between the mutually facing inner surfaces (a larger width of the waveguide 1), which are parallel to each other, of a single waveguide 1. In other words, the distance between the inner surfaces of the adjacent waveguides 1 is set shorter than the distance between the mutually facing inner surfaces, which are parallel to each other, of the waveguide 1.

If the pressure inside the vacuum vessel 5 is lowered, a differential gaseous pressure between the pressure substantially equal to the atmospheric pressure and the pressure substantially equal to vacuum, i.e., about 1 kg/cm², is applied to the electromagnetic wave radiating window 4. Such being the situation, it is necessary for the electromagnetic wave radiating window 4 to have a thickness large enough to withstand the differential gaseous pressure noted above.

If the electromagnetic wave radiating window 4 is formed of a circular synthetic quartz plate having a diameter of about 300 mm or a rectangular synthetic quartz plate which is 250 mm square, it is necessary for the electromagnetic wave radiating window 4 to have a thickness of about 30 mm, as shown in Table 1 below. If the thickness of the electromagnetic wave radiating window 4 is increased, the loss of the electromagnetic wave is increased. Particularly, when it comes to a plasma processing apparatus used for applying a plasma processing to a large substrate sized about 1 meter square, the electromagnetic wave radiating window 4 is rendered excessively thick so as to make it impossible to apply a plasma processing to a substrate. Such being the situation, the plasma processing apparatus according to the first embodiment of the present invention comprises six electromagnetic wave radiating windows 4 each sized at 8 cm×55 cm and the vacuum state is maintained between these six electromagnetic wave radiating windows 4 and the vacuum vessel 5. As a result, it is possible to set the thickness of the electromagnetic wave radiating window 4 at about 30 mm.

TABLE 1
(Relationship between window size and required
thickness of synthetic quartz plate)

| | diameter | diameter | | |
|---|---|---|---|---|
| window | of 6 | of 300 | 250 mm | 300 mm |
| size | inches | mm | square | square |
| thickness | 14.3 mm | 30 mm | 30.6 mm | 36.8 mm |
| of | | | | |
| synthetic | | | | |
| quartz | | | | |
| plate | | | | |

The plasma processing apparatus for this embodiment comprises a plurality of rectangular waveguides 1 (six waveguides 1 being shown in the drawing) and a waveguide portion overlapping with the rectangular waveguides 1 and serving to distribute an electromagnetic wave, i.e., the electromagnetic wave-distributing waveguide portion 17. Also, in this embodiment, the vacuum state is maintained in the clearance between the plural electromagnetic wave radiating windows 4 and the vacuum vessel 5.

In the first embodiment of the present invention, a plurality of electromagnetic wave radiating windows 4 are arranged in a manner to correspond to a plurality of slots 2 formed in the rectangular waveguide 1. In this case, the area of the individual electromagnetic wave radiating window 4 can be made small, compared with the case where a single electromagnetic wave radiating window is formed to cover a plurality of slots 2. It follows that a large plasma processing apparatus can be achieved so as to make it possible to apply a plasma processing to the substrate 8 having a large surface area under a uniform plasma density. Where the substrate is sized small, it is possible to form a single electromagnetic wave radiating window 4 in a manner to cover a plurality of rectangular waveguides 1.

Where a plurality of electromagnetic wave radiating windows 4 each made of a dielectric body are arranged in the vacuum vessel 5 as in the first embodiment of the present invention, it is necessary to use beams 11 for supporting these electromagnetic wave radiating windows 4. In general, the beam 11 is made of a metal. However, if electrons, etc. within the plasma are caused to disappear by the beam 11 made of a metal, the plasma is unlikely to be expanded into the portion of the beam 11 (inner surface of the beam 11 ). Under the circumstances, it is desirable for the inner surface of at least the beam 11 constituting a part of the wall of the vacuum vessel 5 to be covered with a dielectric material. In the case of using such a dielectric layer, it is possible to facilitate the expansion of the plasma into the portion of the beam 11.

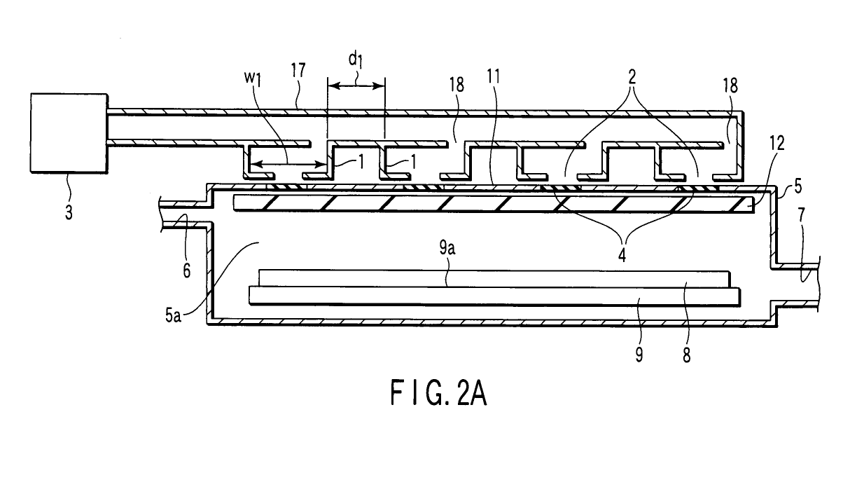

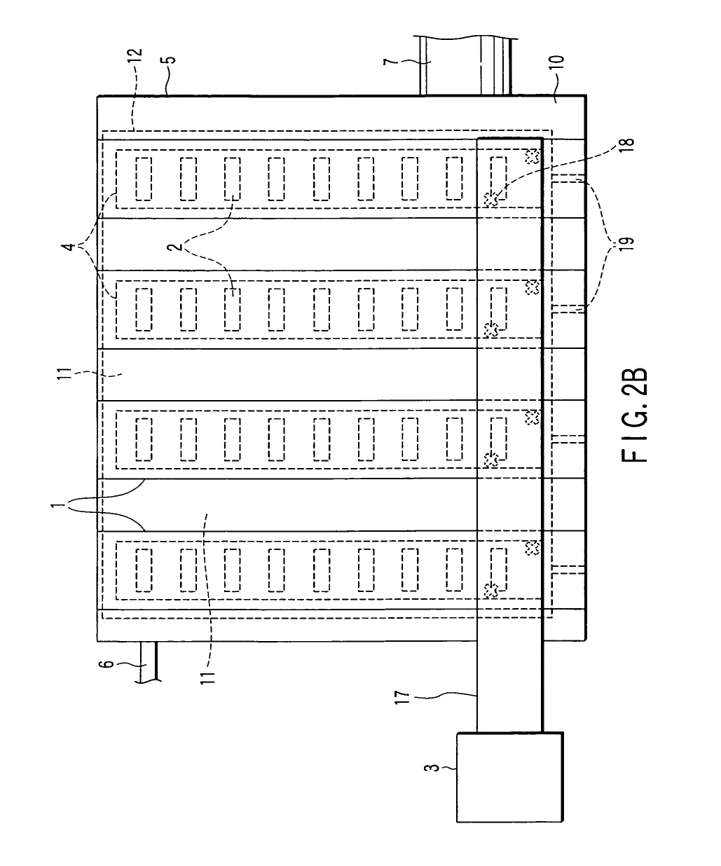

Further, the plural electromagnetic wave radiating windows 4 are mounted to the vacuum vessel 5 in a manner to face the plural slots 2, respectively. As a result, the processing cost of the ceiling plate of the vacuum vessel 5 can be lowered so as to lower the manufacturing cost of the plasma processing apparatus. Also, the plural slots 2 are distributed substantially uniformly over region facing the entire surface area of the substrate 8 that is to be subjected to the plasma processing. It should also be noted that a single electromagnetic wave radiating window 4 is designed to correspond commonly to a plurality of slots 2 (nine slots 2 being shown in FIG. 2 for each rectangular waveguide 1). The plasma processing apparatus for this embodiment comprises a plurality of electromagnetic wave radiating windows 4 (six windows 4 being shown in FIGS. 1 and 2 ).

Incidentally, it is possible for a small clearance to be provided between the waveguide 1 and the beam 11, as shown in FIG. 1E. Also, it is possible to bond hermetically the waveguide 1 to the beam 11 by, for example, welding, as shown in FIG. 1F.

Also, since the adjacent rectangular waveguides 1 are arranged in contact with each other, it is possible to permit easily the slots 2 to be distributed uniformly over the region corresponding to the entire area of the substrate that is to be subjected to the plasma processing. It follows that a large substrate 8 can be subjected to a plasma processing under a uniform plasma density. Incidentally, the technical idea noted above that the plural rectangular waveguides 1 are arranged in contact with each other naturally comprises the situation that the plural waveguides 1 are arranged several centimeters apart from each other. A rectangular waveguide is used as the waveguide 1 in the first embodiment described above. However, the waveguide used in the present invention is not limited to a rectangular waveguide, i.e., a waveguide having a rectangular cross section. As described above, an electromagnetic wave is supplied from a single electromagnetic wave source, i.e., the microwave source 3 in the first embodiment described above, into a plurality of rectangular waveguides 1 through the electromagnetic wave-distributing waveguide portion 17. Naturally, the electromagnetic waves supplied into the plural rectangular waveguides 1 can be made equal to each other in frequency so as to facilitate the design of an antenna radiating an electromagnetic wave having a uniform energy density. Also, in the case of using a plurality of electromagnetic wave sources, it is necessary to design the plasma processing apparatus in view of the interference of the electromagnetic waves generated from the plural electromagnetic wave sources.

The plasma processing apparatus for the first embodiment of the present invention comprises a single microwave source 3 serving to supply an electromagnetic wave to the rectangular waveguide 1. The frequency of the microwave generated from the microwave source 3 is 2.45 GHz. The microwave source generating a microwave having a frequency of 2.45 GHz is manufactured on the mass production basis, and the frequency of 2.45 GHz is used nowadays as the standard frequency. It follows that the microwave source generating a microwave having a frequency of 2.45 GHz is cheap, and various kinds of microwave sources generating a microwave having a frequency of 2.45 GHz are available on the market.

Incidentally, the plasma processing that can be performed by using the plasma processing apparatus according to the first embodiment of the present invention includes a plasma oxidation, a plasma film-formation, a plasma etching, and a plasma ashing. Also, a plasma processing can be applied to a large angular substrate by using the plasma processing apparatus of the present invention. Also, the plasma formed by the plasma processing apparatus of the present invention has a high electron density, a low electron temperature, and a uniform plasma density. It follows that a very good plasma processing, e.g., at least one plasma processing selected from the group consisting of a plasma oxidation, a plasma etching and a plasma film formation, can be performed by the plasma processing method of the present invention using the plasma processing apparatus according to the first embodiment of the present invention.

### SECOND EMBODIMENT

FIG. 2A is a cross sectional view showing the construction of a plasma processing apparatus according to a second embodiment of the present invention, and FIG. 2B is an upper view of the plasma processing apparatus shown in FIG. 2A.

In the plasma processing apparatus according to the first embodiment of the present invention, a plurality of rectangular waveguides 1 are arranged in contact with each other. In the plasma processing apparatus for the second embodiment of the present invention, however, the width w₁ of the rectangular waveguide 1, i.e., the distance in the extending direction of the electromagnetic wave-distributing waveguide portion 17 between the mutually facing inner surfaces, which extend in parallel to each other, of the rectangular waveguide 1 is set at 9 cm, and the distance d₁ between the inner surfaces of the adjacent rectangular waveguides 1 is set at 7 cm. It is desirable for the distance d₁ noted above to be set such that an electromagnetic wave is radiated uniformly from the slots 2 into the vacuum vessel 5 through the electromagnetic wave radiating windows 4. The light emitting state of the plasma generated by changing the distance d₁ between the adjacent waveguides 1 was observed by a CCD camera arranged below the lower surface of the vacuum vessel 5. According to this experiment, a uniform plasma was generated within the vacuum vessel 5 in the case where the waveguides 1 were arranged under the state that the distance d₁ between the inner surfaces of the adjacent waveguides 1 was close to and not larger than the width w₁, i.e., the distance between the mutually facing inner surfaces of the waveguide 1. The experimental data support that it is desirable for the distance d₁ between the inner surfaces of the adjacent waveguides 1 to be set smaller than the width w₁ noted above.

### THIRD EMBODIMENT

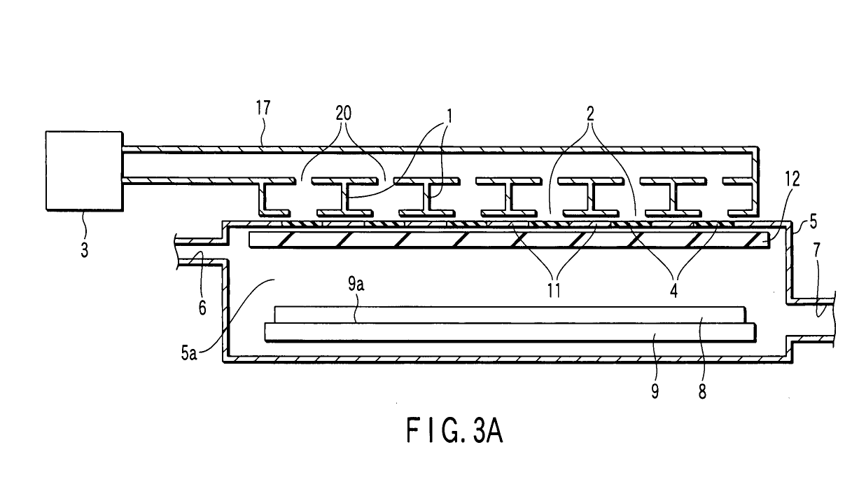

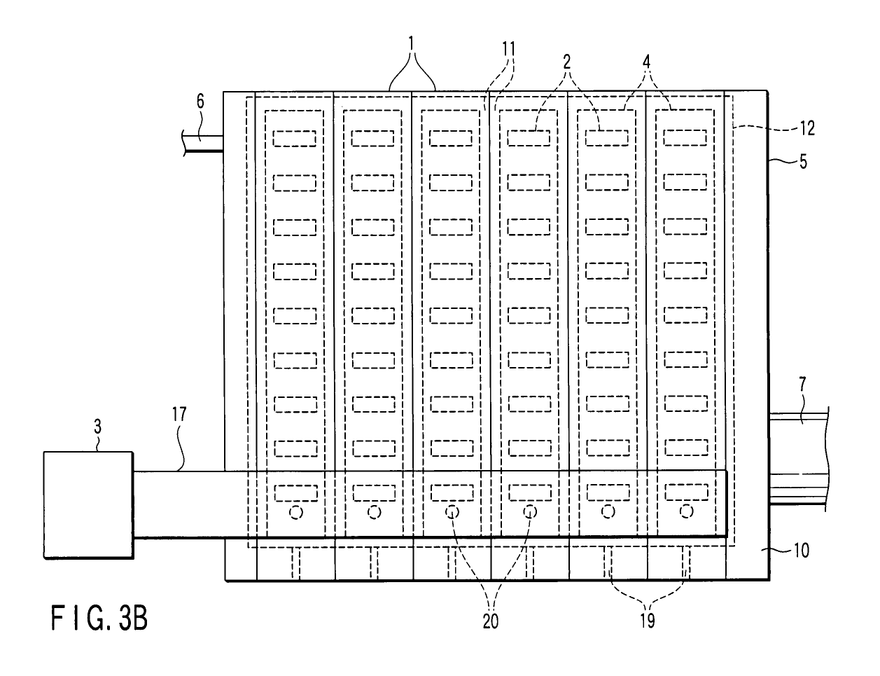

FIG. 3A is a cross sectional view showing the construction of a plasma processing apparatus according to a third embodiment of the present invention, and FIG. 3B is an upper view of the plasma processing apparatus shown in FIG. 3A.

In the plasma processing apparatus according to the first embodiment of the present invention, the electromagnetic wave-distributing waveguide portion 17 and each of the waveguides 1 extend in directions perpendicular to each other, and the electromagnetic wave-distributing waveguide portion 17 is coupled with each of the waveguides 1 by using the coupling hole section 18 having two cross-shaped holes.

The particular construction is known to the art as the cross-guide coupler. In the plasma processing apparatus according to the third embodiment of the present invention, however, a circular coupling hole 20 is formed in the central portion of the overlapping region between the electromagnetic wave-distributing waveguide portion 17 and each of the waveguides l so as to permit the electromagnetic wave-distributing waveguide portion 17 to be coupled with each of the waveguides 1 via the coupling hole 20. The particular construction is known to the art as the bete-hole type directional coupler. In the third embodiment of the present invention, the extending directions of the electromagnetic wave-distributing waveguide portion 17 and each of the waveguides 1 is substantially perpendicular to each other, as shown in FIG. 3B.

However, it is possible for the angle θ made between the extending directions of the electromagnetic wave-distributing waveguide portion 17 and each of the waveguides 1 to fall within a range of between 0° and 90°, i.e., 0°<θ<90°. The coupling degree and the directivity can be determined in accordance with the value of the angle θ as known to the art as a design method of the bete-hole type directional coupler. In the case of arranging the particular directional coupler, the plasma processing apparatus can be designed easily by changing the coupling degree, even if the plural waveguides are not equal to each other in length.

### FOURTH EMBODIMENT

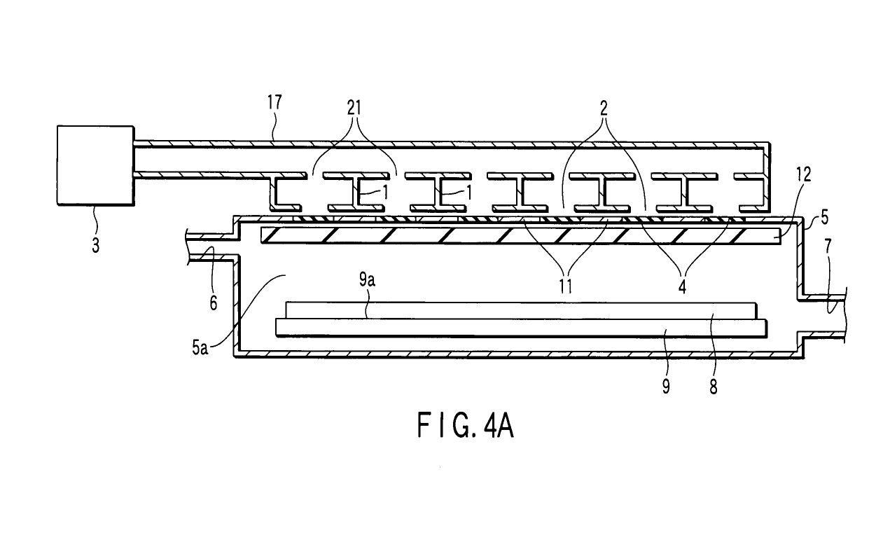

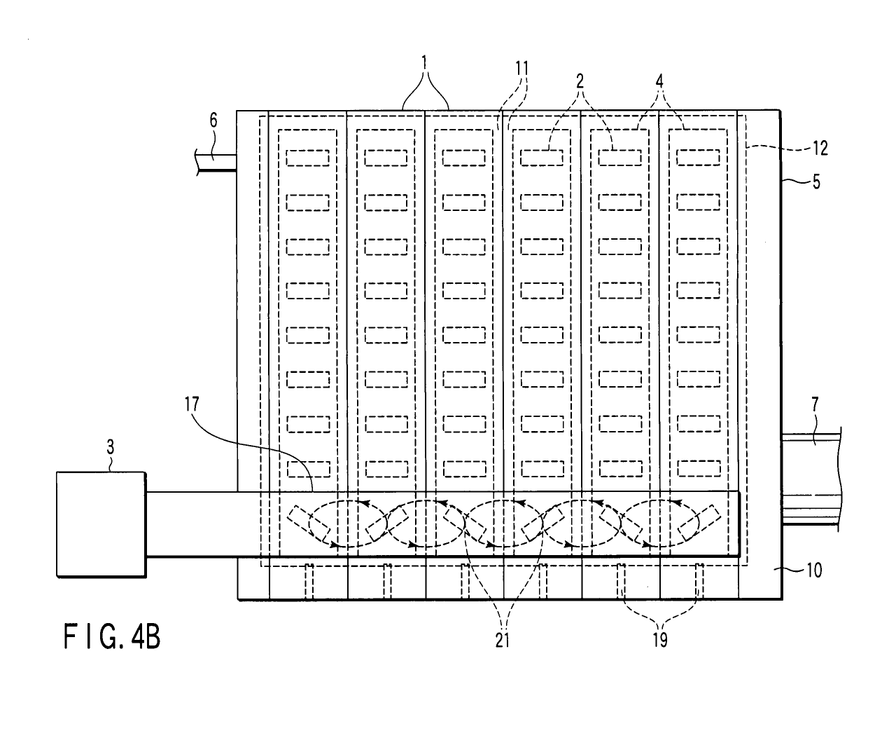

FIG. 4A is a cross sectional view showing the construction of a plasma processing apparatus according to a fourth embodiment of the present invention, and FIG. 4B is an upper view of the plasma processing apparatus shown in FIG. 4A.

In the plasma processing apparatus according to the fourth embodiment of the present invention, the electromagnetic wave-distributing waveguide portion 17 is coupled with each of the waveguides 1 via oblong coupling holes 21 inclined in alternately opposite directions relative to the extending direction of the electromagnetic wave-distributing waveguide portion 17. The oblong coupling holes 21 are inclined in alternately opposite directions by ±45° relative to the extending direction of the electromagnetic wave-distributing waveguide portion 17.

In other words, oblong coupling holes inclined in alternately opposite directions by about 45° relative to the extending direction of the electromagnetic wave-distributing waveguide portion 17, i.e., the oblong coupling holes 21, are formed in the central portion of the overlapping region between the electromagnetic wave-distributing waveguide portion 17 and each of the waveguides 1. The electromagnetic wave-distributing waveguide portion 17 is coupled with each of the waveguides 1 via the oblong coupling hole 21. By the particular arrangement, magnetic lines of force are formed inside the electromagnetic wave-distributing waveguide portion 17 as denoted by ellipses of broken lines shown in FIG. 4B. When an electric current flows to cross the oblong coupling hole 21, an electric field is generated in a direction perpendicular to the coupling hole 21. On the other hand, the entire region of the magnetic field is parallel to the surface of a conductor and, thus, the direction of the magnetic field and flowing direction of the current are kept perpendicular to each other. It follows that, when it comes to the magnetic line of force, it is possible for that component of the magnetic line of force which is parallel to the coupling hole 21 to pass through the coupling hole 21. The component of the magnetic line of force as passing through the coupling hole 21 forms an ellipse in an oblique direction because the coupling hole 21 is inclined. However, the magnetic line of force forms a clear ellipse when the electromagnetic wave is propagated within the waveguide 1.

### FIFTH EMBODIMENT

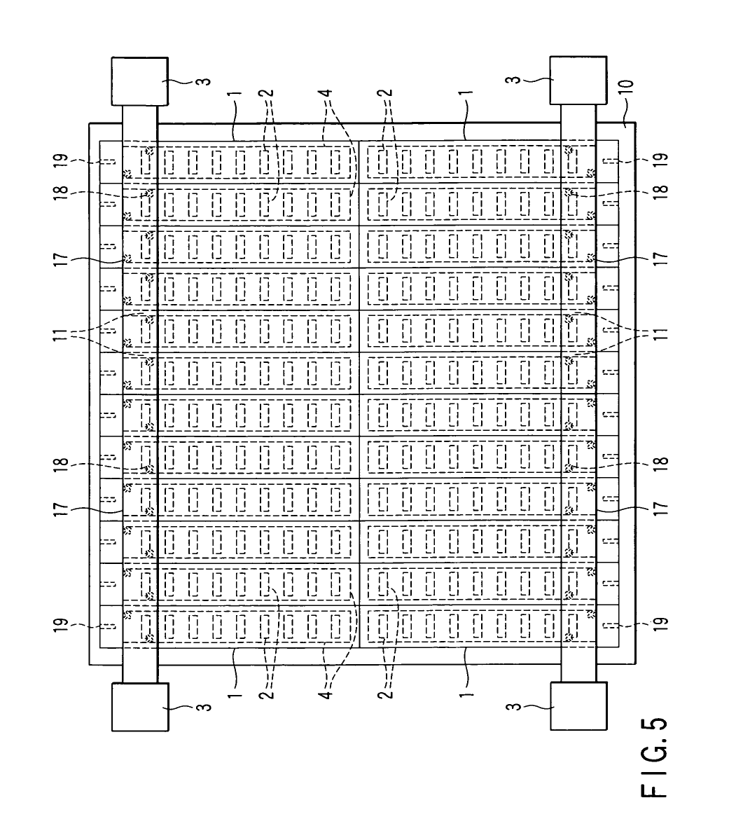

FIG. 5 is an upper view schematically showing the construction of a plasma processing apparatus according to a fifth embodiment of the present invention.

Where the microwave source 3 has a sufficiently large maximum output, it suffices to use a single microwave source 3 for supplying an electromagnetic wave into the vacuum vessel as in the plasma processing apparatus according to the first embodiment of the present invention. However, the area of the substrate that is to be subjected to the plasma processing is limited in the case of using only one microwave source 3. In other words, since the maximum output of the single microwave source 3 is limited, a plurality of microwave sources 3 are included in the plasma processing apparatus according to the fifth embodiment of the present invention. The plasma processing apparatus can be operated under a large power in the case of supplying a microwave from a plurality of microwave sources 3 into the vacuum vessel 5. It follows that it is possible to achieve a plasma processing apparatus capable of applying a plasma processing to the substrate having a large surface area.

As shown in the drawing, the plasma processing apparatus for this embodiment comprises four microwave sources 3 and, thus, a substrate having a surface area 4 times as large as that of an ordinary substrate can be subjected to the plasma processing by the plasma processing apparatus according to the fifth embodiment of the present invention. For example, in the case of using a single electromagnetic wave source of 10 kW, the largest surface area of the substrate that can be subjected to the plasma processing is 100 cm×120 cm. On the other hand, in the case of using four electro-magnetic wave sources 3 each having an output of 10 kW, the plasma processing apparatus is capable of handling the substrate having a surface area 4 times as large as that of the substrate that can be subjected to the plasma processing by the plasma processing apparatus comprising only one electromagnetic wave source 3 of 10 kW. For example, in the case of using four electro-magnetic wave sources 3 each having an output of 10 kW, the plasma processing apparatus can be used for processing the substrate sized up to 200 cm×240 cm.

In the case of using a plurality of-microwave sources 3, an interference takes place among the microwaves generated from the plural microwave sources 3, with the result that it is possible for the plasma characteristics to be changed so as to lower the stability of the plasma. Such being the situation, in the case of using a plurality of microwave sources 3, it is advisable to set the adjacent microwave sources 3 at different frequencies. In this case, the influences given by the microwave source 3 can be alleviated so as to prevent the interference between the electromagnetic waves generated from the different microwave sources 3. It follows that the stability of the plasma can be improved.

It should also be noted that the microwave source generating a microwave having a frequency of 2.45 GHz is manufactured on the mass production basis. It follows that the plasma processing apparatus can be manufactured at a low cost in the case where the frequency of the microwave generated from the microwave source 3 is set at 2.45 GHz. It is possible to change slightly the frequency, which is 2.45 GHz, of the microwave generated from the microwave source 3 so as to make it possible to permit the adjacent microwave sources 3 to generate microwaves having slightly different frequencies.

### SIXTH EMBODIMENT

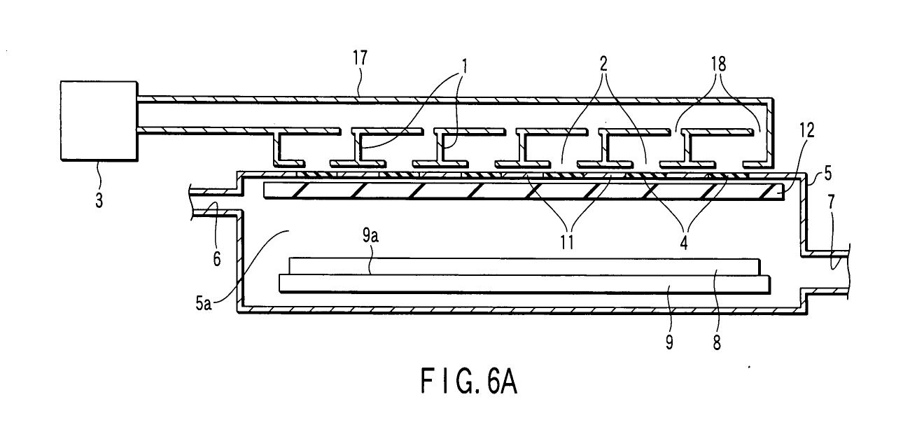

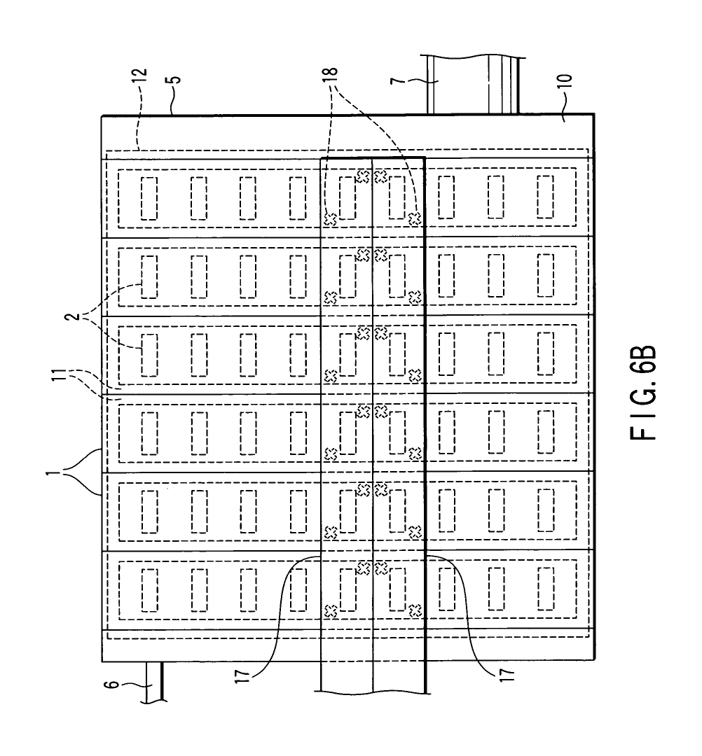

FIG. 6A is a cross sectional view showing the construction of a plasma processing apparatus according to a sixth embodiment of the present invention, and FIG. 6B is an upper view of the plasma processing apparatus shown in FIG. 6A.

The plasma processing apparatus according to the sixth embodiment of the present invention comprises a pair of electromagnetic wave-distributing waveguide portions 17 arranged in parallel and positioned contiguous to each other. The plasma processing apparatus for this embodiment also comprises a plurality of waveguides 1 extending in one direction perpendicular to the extending direction of one of the paired electromagnetic wave-distributing waveguide portions 17. Likewise, a plurality of other waveguides 1 are arranged to extend in another direction perpendicular to the extending direction of the other electromagnetic wave-distributing waveguide portion 17. In this embodiment, each of the waveguides 1 extending in one direction and each of the waveguides 1 extending in another direction are positioned to form a straight line.

The microwave oscillated in the oscillator 31 a included in the microwave source 3 is transmitted by the paired electromagnetic wave-distributing waveguide portions 17 arranged in parallel and positioned contiguous to each other so as to be distributed to each of the waveguides 1 extending in one direction and to each of the waveguides 1 extending in another direction. Then, the microwave distributed to each of the waveguides 1 is radiated from the slot 2 constituting a waveguide antenna into the vacuum vessel 5 through the electromagnetic wave radiating window 4. Each of the waveguides 1 is positioned to overlap with and extends to cross the paired electromagnetic wave-distributing waveguide portions 17 at substantially the right angles. It is possible not to form the slots 2 in the region corresponding to the overlapping portion between the electromagnetic wave-distributing waveguide portion 17 and the waveguide 1. However, the plasma can be generated uniformly within the vacuum vessel 5 if the slots 2 are formed in the region corresponding to the overlapping portion between the electromagnetic wave-distributing waveguide portion 17 and the waveguide 1, as shown in the drawing.

In the plasma processing apparatus according to the sixth embodiment of the present invention, it is necessary to arrange a pair of electromagnetic wave-distributing waveguide portions 17 so as to distribute the electromagnetic wave in two directions. However, compared with the plasma processing apparatus according to any of the first, second and third embodiments of present invention described previously, each waveguide 1 can be made shorter in the sixth embodiment so as to easily permit improving the uniformity of the plasma in the longitudinal direction of the waveguide 1.

### SEVENTH EMBODIMENT

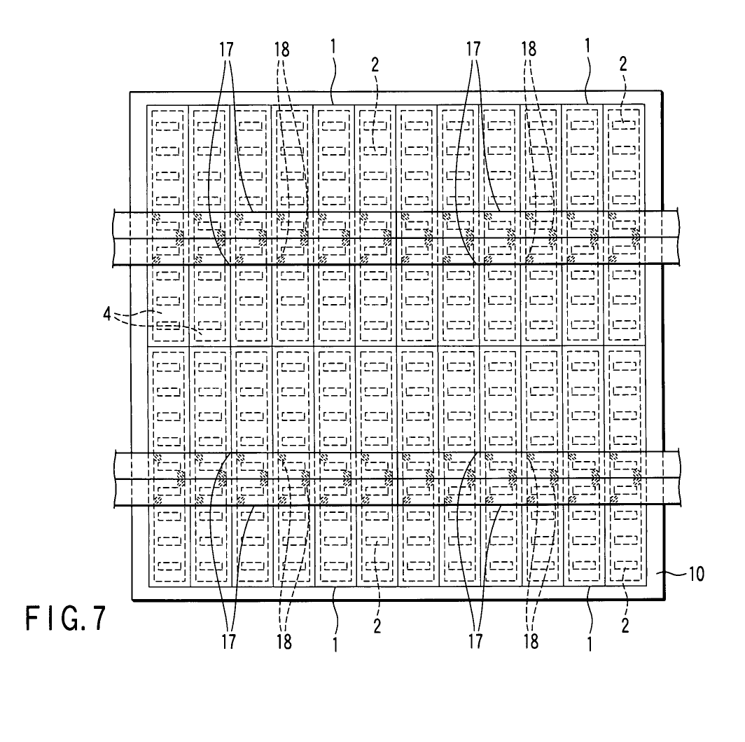

FIG. 7 is an upper view showing the construction of a plasma processing apparatus according to a seventh embodiment of the present invention.

The plasma processing apparatus for the seventh embodiment is substantially equal to the plasma processing apparatus for the sixth embodiment, except that four microwave sources 3 are included in the plasma processing apparatus for the seventh embodiment. It follows that the plasma processing apparatus for the seventh embodiment is capable of handling a substrate having a surface area four times as large as that of the substrate handled by the plasma processing apparatus for the sixth embodiment. For example, in the case of using four electromagnetic wave sources each having an output of 10 kW, it is possible to handle a substrate having the maximum surface area of 200 cm×240 cm.

In the plasma processing apparatus according to each of the first to seventh embodiments of the present invention described above, a microwave source is used mainly as the electromagnetic wave source. However, the electromagnetic wave source used in the present invention is not limited to the microwave source. Also, a linear waveguide is used as the electromagnetic wave-distributing waveguide portion 17 in each of the first to seventh embodiments of the present invention. However, the electromagnetic wave-distributing waveguide portion 17 is not limited to a linear waveguide. Also, the waveguide 1 used in the present invention is not limited to a rectangular waveguide, i.e., a waveguide having a rectangular cross section. Further, the waveguide 1 used in each of the first to seventh embodiments of the present invention is of a double-layer structure. However, it is also possible to use in the present invention a waveguide of a multi-layer structure such as a three-layer structure or a four-layer structure.

### EIGHTH EMBODIMENT

A manufacturing process of a polycrystalline silicon thin film transistor (poly-Si TFT) used in a liquid crystal display device will now be described. The poly-Si TFT is formed on a glass substrate by using the plasma processing apparatus according to the embodiment of the present invention.

The significance of the poly-Si TFT and the required properties of the gate insulating film will now be described first.

In general, a low temperature poly-Si (polycrystalline silicon) thin film transistor (poly-Si TFT) has electrical characteristics higher than those of an amorphous thin film transistor (a-Si TFT) and is said to be used for forming various electronic circuits on a glass substrate for a liquid crystal display device. One of the technologies required for forming a satisfactory low temperature poly-Si TFT is the formation of a gate insulating film. Such being the situation, it is of high importance to develop a technique for forming a good gate insulating film.

The gate insulating film for a low temperature poly-Si TFT and the gate insulating film for an integrated circuit, which are used for the similar purposes, quite differ from each other in the required properties. First of all, the process temperature for forming the gate insulating film for an integrated circuit is not lower than 950° C. On the other hand, in the case of forming the gate insulating film for the low temperature poly-Si TFT, it is necessary for the process temperature to be not higher than 600° C. because it is desirable to use glass or a plastic material for forming the gate insulating film. The difference in the substrate area should also be considered. Specifically, in the case of forming an integrated circuit, used is, for example, a single crystalline silicon wafer having a diameter of 30 cm. On the other hand, in the case of forming a low temperature poly-Si TFT, used is, for example, a glass substrate sized at about 70 cm×90 cm or more. In other words, the substrate area in the case of forming a low temperature poly-Si TFT nowadays is more than about 9 times as large as the substrate area in the case of manufacturing an integrated circuit. In addition, a substrate having a larger area is expected to be used in future in the manufacture of a low temperature poly-Si TFT.

An additional difference to be noted is the surface roughness. Specifically, the single crystalline silicon wafer used for manufacturing an integrated circuit can be made smooth in the atomic level. The target value in future in the surface roughness is 0.1 nm in the case of the single crystalline silicon wafer. On the other hand, when it comes to the low temperature poly-Si TFT, the volume is expanded when a molten silicon is converted into a solid, starting with the nucleus, so as to achieve the crystal growth. During the crystal growth, the crystal grains are caused to collide against each other so as to form an upheaved portion in the grain boundary. As a result, about 50 nm of a projection is formed in the low temperature poly-Si substrate. Also, the island-like poly-Si region in the channel portion has a step of 50 nm to 200 nm. Such being the situation, for manufacturing a good low temperature poly-Si TFT, it is necessary to develop a gate insulating film capable of sufficiently overcoming the projection problem.

The difference in the required properties will now be described in respect of the electrical defect density of the gate insulating film. Specifically, the area of a single element is 1.5 cm² in the integrated circuit, e.g., a PC processor, and 900 cm² in the 15 inch-liquid crystal display. In other words, the required specification of the electrical defect density for the 15-inch liquid crystal display is 600 times as much as that for the PC processor. The channel area in the central portion of the transistor is 0.14 μm×0.14 μm for the integrated circuit, and 1.0 μm ×1.0 μm for the minimum TFT. Also, the peripheral circuit forming a part of the 15-inch liquid crystal display includes a TFT having a larger channel area, with the result that it is possible for the channel area for the 15-inch liquid crystal display to be about 100 times as large as that of the integrated circuit. The number of TFTs included in the liquid crystal display screen is 5,760,000 in UXGA (i.e., 1,600×1,200×3=5,760,000). The number of transistors included in the peripheral integrated circuit, which is incorporated in the TFT substrate, is considered to be on the order of several millions, though the number in question depends on the circuit that is incorporated in the TFT substrate. Such being the situation, the total number of transistors included in the system panel comprising the peripheral circuit is several times as large as that in the peripheral integrated circuit. It follows that the sum of the channel areas within a single element in the case of the low temperature poly-Si TFT is estimated to be about several hundred times as large as that in the case of the integrated circuit. In other words, in order to make the good article rate of the TFT single panel equal to that of the integrated circuit single chip, it is necessary to lower the electrical defect density in the gate insulating film to one-several hundredth.

As described above, the manufacture of a low temperature poly-Si TFT differs from the manufacture of an integrated circuit. In the case of manufacturing a low temperature poly-Si TFT, it is absolutely necessary to develop the technique for forming an insulating film adapted for the low temperature poly-Si TFT, which satisfies the requirements given below:

(1) The film can be formed under temperatures not higher than 600° C.

(2) The film is capable of covering a large area and a large irregularity on the surface.

(3) The electrical defect density can be markedly improved.

(4) A good Si/SiO₂ interface can be formed.

Under the circumstances, it is of high importance to develop a plasma processing apparatus that permits applying an oxidation, a film formation, and an etching to an angular substrate having a large area.

A manufacturing process of a polycrystalline silicon thin film transistor (poly-Si TFT) used in a liquid crystal display device will now be described. The poly-Si TFT is formed on a glass substrate by using the plasma processing apparatus according to the embodiment of the present invention.

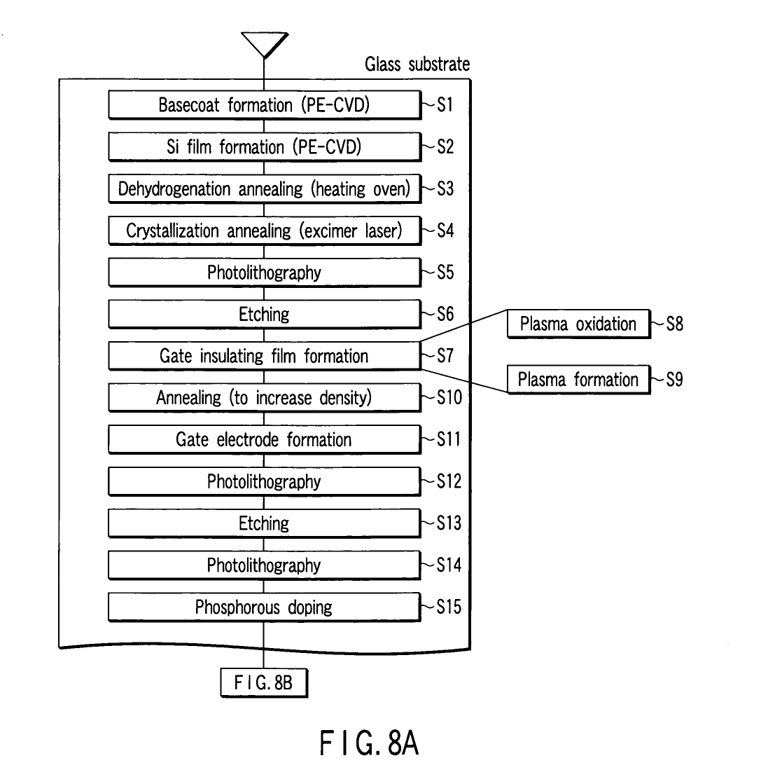

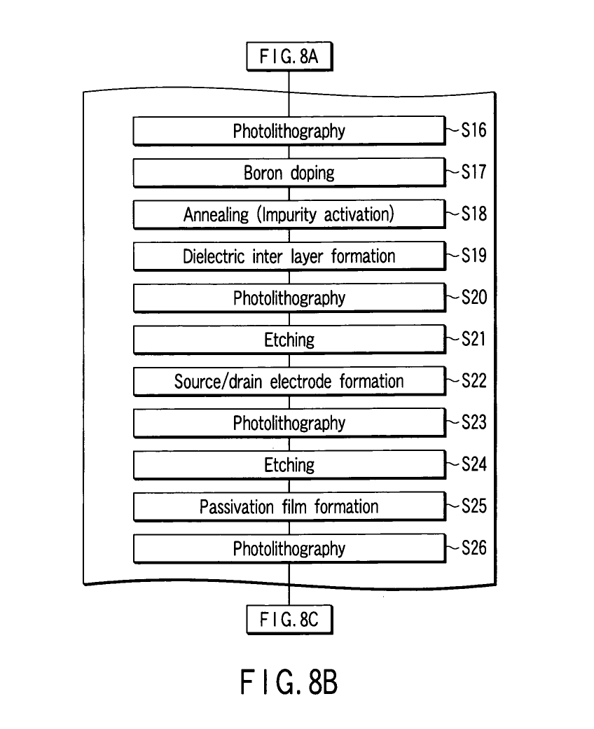

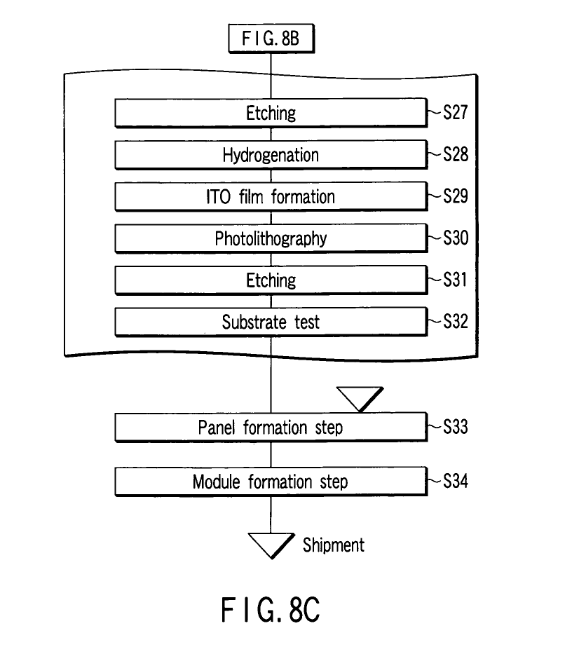

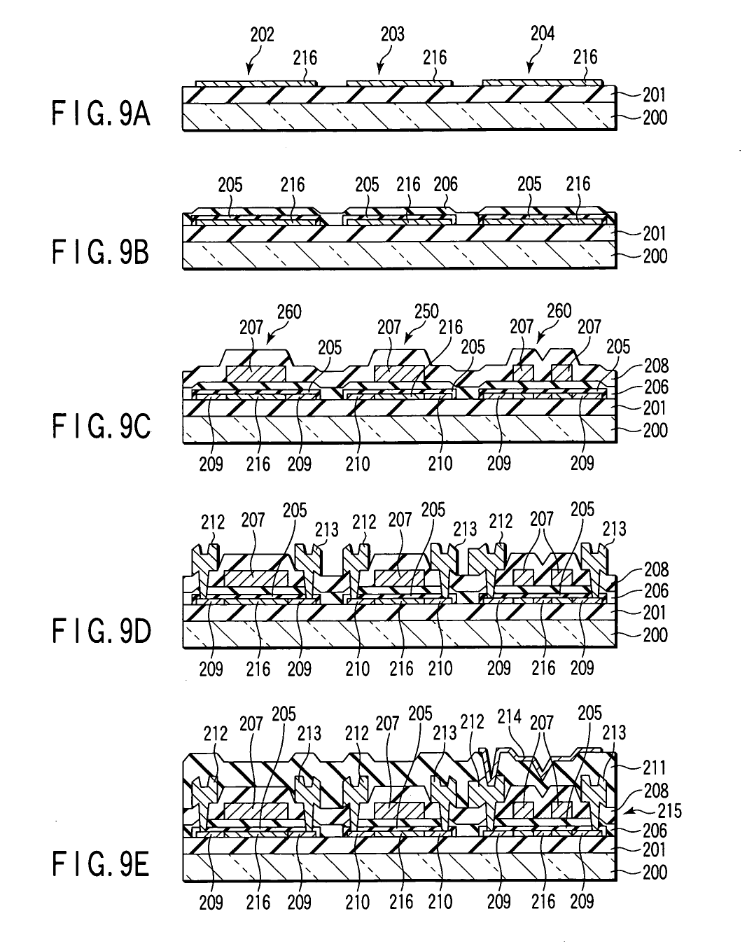

FIGS. 8A, 8B and 8C are flow charts collectively showing the process of manufacturing n-channel and p-channel poly-Si thin film transistors for a liquid crystal display device by the plasma processing method of the present invention. On the other hand, FIGS. 9A to 9E are cross sectional views showing the situations of the substrates in each process stage.

In the process step S1 shown in FIG. 8A, a silicon oxide film (SiO₂ film) was formed as a base coat film 201 in a thickness of 200 nm on a washed glass substrate 200 by the PE-CVD method (plasma CVD method) using a TEOS gas, as shown in FIG. 9A. A glass plate sized at 700 mm×600 mm×1.1 mm was used as the glass substrate 200.

Then, in the process step S2 shown in FIG. 8A, an amorphous silicon film was formed in a thickness of 50 nm by the PE-CVD method using a SiH₄ gas and a H₂ gas. The amorphous silicon film thus formed contained 5 to 15 atomic % of hydrogen. Therefore, if the amorphous silicon film is irradiated with a laser beam, hydrogen is rendered gaseous so as to cause a rapid volume expansion and to blow away the film. Such being the situation, the temperature of the glass substrate 200 having the amorphous silicon film formed thereon was maintained at 350° C. or higher, at which the bond of the hydrogen molecule was broken, for about one hour so as to release the hydrogen atoms in the process step S3 shown in FIG. 8A. In other words, the dehydrogenation annealing was performed in process step S3.

After the dehydrogenation annealing, the amorphous silicon film formed on the glass substrate 200 was irradiated by using an optical system with a pulse light beam (670 mJ/pulse) emitted from a xenon chloride (XeCl) excimer laser light source. The amorphous silicon film was irradiated with the pulse light beam at an intensity of 360 mJ/cm². The wavelength of the pulse light beam was 308 nm, and the pulse light beam was shaped to have a cross section sized at 0.8 mm×130 mm. The amorphous silicon film absorbing the laser light beam was melted so as to form a liquid phase and, then, the temperature of the liquid phase was lowered and the liquid phase was solidified so as to obtain a polycrystalline silicon layer 216. The laser light beam was in the form of a pulse of 200 Hz, and the melting and the solidification were finished within the time of one pulse. It follows that the melting and the solidification were repeated within each pulse during the laser beam irradiation. A large area can be crystallized by applying the laser light beam irradiation while moving the glass substrate 200. In order to suppress the nonuniformity in the characteristics, the irradiation was performed by overlapping the individual irradiating regions of the laser light beam by 95 to 97.5% in process step S4 shown in FIG. 8A.

The polycrystalline silicon layer was subjected to a photolithography process in process step S5 shown in FIG. 8A and, then, to an etching process in process step S6 shown in FIG. 8A so as to pattern the polycrystalline silicon layer 216 in a manner to form island regions corresponding to the source region, the channel and the drain region. As a result, formed were an n-channel TFT region 202, a p-channel TFT region 203 and a pixel portion TFT region 204, as shown in FIG. 9A.

In the next step, a gate insulating film is formed and the interface-between the gate insulating film and the channel region of the semiconductor layer (polycrystalline silicon layer 216) is processed in process step S7 shown in FIG. 8A. The process step 7 is most important in the manufacture of the poly-Si TFT.

The plasma processing apparatus according to the first embodiment of the present invention, which is shown in FIG. 1A, was used in the process step S7.

Specifically, the glass substrate 200 having the island-like polycrystalline silicon layer 216 formed on the base coat film 201 as shown in FIG. 9A was set on the support table 9 heated to 350° C. Then, a mixed gas consisting of an Ar gas and an oxygen gas mixed at a mixing ratio of “Ar/(Ar+O₂)=95%” was introduced into the process chamber 5a, and the pressure of the mixed gas within the process chamber 5a was maintained at 80 Pa. Then, a power of 5 kW, which was supplied from the microwave source generating a microwave having a frequency of 2.45 GHz, was applied to the process chamber 5a so as to form an oxygen plasma, thereby performing a plasma oxidation.

Within the oxygen plasma, the oxygen gas is decomposed into a highly reactive oxygen atom active species, and the island-like polycrystalline silicon layer 216 is oxidized by the oxygen atom active species. As a result, a photo-oxidation film consisting of SiO₂ is formed so as to provide a gate insulating film 205, which is a first insulating film, as shown in FIG. 9B. In the process step S8 shown in FIG. 8A, the first gate insulating film 205 (first insulating film) was formed in a thickness of about 3 nm in 3 minutes.

After formation of the first gate insulating film 205, the gas used for the plasma oxidation was discharged from within the process chamber 5a, followed by supplying a TEOS gas at a flow rate of 30 sccm and an oxygen gas at a flow rate of 7500 sccm into the process chamber 5a while maintaining the substrate temperature at 350° C. for consecutively forming a SiO₂ film. In this fashion, the inner pressure of the process chamber 5a was set at 267 Pa (2 Torr), and the power of the microwave source was set at 450 W. Under this condition, a second gate insulating film 206 (second insulating film) consisting of a SiO₂ film was formed on the first gate insulating film 205. It was possible to form the second gate insulating film 206 in a thickness of 30 nm in two minutes (process step S9 shown in FIG. 8A).

It is possible to carry out consecutively under vacuum the plasma oxidation step (process step S8 shown in FIG. 8A) and the step for forming the first gate insulating film 205 by the high density plasma CVD method low in damage (process step S9 shown in FIG. 8A) without decreasing the productivity. As a result, it is possible to provide a good interface between the semiconductor layer (island-like poly-Si layer 216 ) and the first gate insulating film 205. In addition, it is possible to form promptly a thick insulating film that can be used practically.

The conventional method was employed in the subsequent steps so as to form a poly-Si TFT.

To be more specific, the glass substrate 200 was annealed under a nitrogen gas for 2 hours, with the substrate temperature set at 350° C., so as to increase the density of the first gate insulating film 205 consisting of a SiO2 film (process step S10 shown in FIG. 8A). By this annealing treatment, the density of the SiO₂ film was increased so as to suppress the current leakage and to improve the pressure resistance.

In the next step, a Ti film used as a barrier metal film was formed in a thickness of 100 nm by a sputtering method, followed by forming an Al metal layer in a thickness of 400 nm by a sputtering method (process step S11 shown in FIG. 8A). The Al metal layer thus formed was patterned by a photolithography method (process steps S12 and S13 shown in FIG. 8A) so as to form a gate electrode 207 as shown in FIG. 9C.

After formation of the gate electrode 207, a p-channel TFT 250 alone was covered with photoresist (not shown) by the photolithography process (process step S14 shown in FIG. 8A). Then, an n⁺-source·drain contact portion 209 included in an n-channel TFT 260 was doped with phosphorus by an ion doping method, with the gate electrode 207 used as a mask (process step S15 shown in FIG. BA). The phosphorus doping was performed at a concentration of 6×10¹⁵/cm² under an accelerating energy of 80 keV.

In the next step, an n-channel TFT 260 included in each of the n-channel TFT region 202 and the pixel section TFT region 204 was covered with a photoresist by the photolithography process (process step S16 shown in FIG. 8B). Then, a p⁺-source·drain contact portion 210 included in the p-channel TFT 250 of the p-channel TFT region 203 (FIG. 9A) was doped with boron by an ion doping method, with the gate electrode 207 used as a mask (process step S17 shown in FIG. 8B). The boron doping was performed at a concentration of 1×10¹⁶/cm² under an accelerating energy of 60 keV.

Further, the glass substrate 200 was annealed for 2 hours with the substrate temperature set at 350° C. so as to activate the phosphorus ions and the boron ions introduced into the source·drain contact portions by the ion doping method (process step S 18 shown in FIG. 8B). Then, an interlayer insulating film 208 consisting of a SiO₂ film was formed by a plasma CVD method using a TEOS gas, as shown in FIG. 9C (process step S19 shown in FIG. 8B).

In the next step, contact holes leading to the n⁺ source·drain contact portion 209 and the p⁺ source·drain contact portion 210 were formed in the second gate insulating film 206 and the interlayer insulating film 208 by the photolithography process (process step S20 shown in FIG. 8B) and the etching process (process step S21 shown in FIG. 8B), as shown in FIG. 9D. Then, a Ti barrier metal layer (not shown) was formed in a thickness of 100 nm by a sputtering method, followed by forming an Al layer in a thickness of 400 nm by a sputtering method (process step S22 shown in FIG. 8B). Further, a source electrode 213 and a drain electrode 212 were formed by patterning the laminate structure of the Ti barrier metal layer and the Al layer by the photolithography process (process step S23 shown in FIG. 8B) and the etching process (process step S24 shown in FIG. 8B), as shown in FIG. 1D.

In the next step, a protective film 211 consisting of a SiO₂ film was formed in a thickness of 300 nm by a plasma CVD method (process step S25 shown in FIG. 8B), as shown in FIG. 9E. Then, a contact hole leading to a pixel electrode 214 (referred to herein later) consisting of an ITO film was formed in the drain electrode 212 included in the n-channel TFT 260 (FIG. 9C) formed in the pixel portion TFT region 204 (FIG. 9A) by the photolithography process (process step S26 shown in FIG. 8B) and the etching process (process step S27 shown in FIG. 8C).

In the next step, a hydrogen plasma processing (hydrogenation) was performed for 3 minutes within a one-by-one multi-chamber sputtering apparatus under the conditions that the substrate temperature was set at 350° C., the H₂ gas flow rate was set at 1,000 sccm, the gas pressure was set at 173 Pa (1.3 Torr), and the RF power source power was set at 450 W (process step S28 shown in FIG. 8C).

Then, the substrate was moved into another process chamber so as to form an ITO film in a thickness of 150 nm (process step S29 shown in FIG. 8C). Further, the pixel electrode 214 formed of the ITO film was patterned by the photolithography process (process step S30 shown in FIG. 8C) and the etching process (process step S31 shown in FIG. 8C) so as to finish preparation of the TFT substrate 215, as shown in FIG. 9E. Then, the substrate was tested (process step S32 shown in FIG. 8C).

Each of the TFT substrate 215 and a glass substrate (not shown) having a color filter formed thereon was coated with polyimide, and the coated polyimide films were rubbed, followed by bonding these two substrates to each other. Further, the substrate formed by the bonding was cut into individual panels.

The resultant panels were put in a vacuum vessel, and the inlet port of each of the panels was dipped in a liquid crystal put in a dish. Further, the air was introduced into the vessel so as to permit the liquid crystal to be injected into the panel by the air pressure. Still further, the inlet port of the panel was sealed with resin so as to finish preparation of the liquid crystal panel (process step S33 shown in FIG. 8C).

In the next step, a deflecting plate, a peripheral circuit, a back light, a bezel, etc. were mounted to the liquid crystal panel so as to finish preparation of a liquid crystal module (process step S34 shown in FIG. 8C).

The liquid crystal module thus prepared can be used in, for example, a personal computer, a monitor, a television receiver, and a portable terminal.

Where the SiO₂ film was formed by the ordinary plasma CVD method in place of the plasma oxide film, the threshold voltage of the TFT was found to be 1.9V±10.8V. On the other hand, the threshold voltage of the TFT formed by the embodiment of the present invention was found to be improved to 1.5V±0.5V. It is considered reasonable to understand that, in the present invention, an interface between a silicon oxide film and a silicon film is formed within the polycrystalline silicon film, and good interfacial characteristics can be obtained between the silicon oxide film and the polycrystalline silicon film (island-like polycrystalline silicon layer 216), so as to improve the threshold voltage of the TFT as pointed out above. It is also considered reasonable to understand that the bulk characteristics of the insulating film are improved so as to improve the threshold voltage of the TFT in the present invention. It should also be noted that the nonuniformity in the threshold voltage was decreased in the TFTs formed in the embodiment of the present invention so as to markedly improve the good article rate of the liquid crystal modules. Also, the laminate structure consisting of the plasma oxide film and the high density plasma CVD film low in damage makes it possible to obtain a gate insulating film satisfactory in coverage. In addition, the characteristics of the CVD film are satisfactory so as to make it possible to decrease the thickness of the gate insulating film to about 30 nm. Since the gate insulating film included in the conventional TFT has a thickness of about 80 to 100 nm, the TFT formed in this embodiment of the present invention makes it possible to decrease the thickness of the gate insulating film to about ⅓ of the thickness in the conventional TFT, with the result that the on-current was improved to reach a level about 3 times as high as that for the conventional TFT.

Also, a silicon single crystalline wafer (p-type, 8˜12 Ω·cm, diameter of 150 mm, (100)) was disposed on a glass substrate, and a gate insulating film was formed by the method equal to the method according to the eighth embodiment of the present invention. Then, an aluminum film was formed by the vapor deposition employing the resistance heating with a mask disposed on the gate insulating film. A hole having a diameter of 1 mm was formed in the mask used. Then, a baking was applied for 30 minutes at 400° C. under a mixed gas atmosphere containing 96% of a nitrogen gas and 4% of a hydrogen gas. The interface level density, which was measured by using the MOS structure element thus obtained, was found to be 3×10¹⁰ cm^{-2eV-1}. Clearly, it was possible to obtain satisfactory interface characteristics substantially equal to those of the thermal oxide film.

As described above, according to the first to eighth embodiments of the present invention, it is possible to provide a plasma processing apparatus and a plasma processing method, which are highly effective for forming a low temperature poly-Si TFT included in a liquid crystal display panel comprising a glass substrate. In other words, it is possible to provide a plasma processing apparatus and a plasma processing method, which are highly effective for forming by plasma oxidation a thin gate insulating film, good characteristics being exhibited in the interface between the thin gate insulating film thus formed and the single crystalline silicon layer used for forming the channel region.

It should be noted that the first to eighth embodiments of the present invention described above are intended to set forth clearly the technical idea of the present invention and, thus, the technical scope of the present invention is not limited by these embodiments. In other words, each of the factors disclosed in the embodiments of the present invention described above should be construed to cover all the design modifications and the equivalents thereof belonging to the technical scope of the present invention.

As described above, the present invention provides a plasma processing apparatus and a plasma processing method, which permit applying a plasma processing such as a film deposition, a surface modification and an etching to a large angular substrate. In addition, the plasma processing apparatus of the present invention permits forming a plasma having a uniform plasma density. The plasma processing apparatus and the plasma processing method of the present invention are particularly adapted for the manufacture of various displays such as a liquid crystal display, EL, and a plasma display.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A plasma processing apparatus, comprising:
at least one electromagnetic wave source for generating an electromagnetic wave;
an electromagnetic wave-distributing waveguide portion for distributing the electromagnetic wave generated from the electromagnetic wave source;
plurality of waveguides provided on a single plane, each waveguide being coupled with the electromagnetic wave-distributing waveguide portion;
a plurality of slots provided in each of the waveguides;
at least one electromagnetic wave radiating window provided to face each slot; and
a vacuum vessel in which a plasma is generated by the electromagnetic wave radiated from the electro-magnetic wave radiating window,
wherein the electromagnetic wave-distributing waveguide portion is provided on the plural waveguides.

2. A plasma processing apparatus, comprising:
at least one electromagnetic wave source for generating an electromagnetic wave;
an electromagnetic wave-distributing waveguide portion for distributing the electromagnetic wave generated from the electromagnetic wave source;
a plurality of waveguides each having an electric field plane and a magnetic field plane perpendicular to the electric field plane and provided on the same plane;
a plurality of slots provided in each of the waveguides;
at least one electromagnetic wave radiating window provided to face each slot; and
a vacuum vessel in which a plasma is generated by the electromagnetic wave radiated from the electro-magnetic wave radiating window,
wherein the plural waveguides are equal to each other in the length in the propagating direction of the electromagnetic wave, and the electromagnetic wave-distributing waveguide portion is provided on the plural waveguides and coupled with each of the waveguides in the magnetic field plane of the waveguide.

3. A plasma processing apparatus, comprising:
at least one electromagnetic wave source for generating an electromagnetic wave;
an electromagnetic wave-distributing waveguide portion for distributing the electromagnetic wave generated from the electromagnetic wave source;
a plurality of waveguides coupled with the electromagnetic wave-distributing waveguide portion and provided in parallel on the same plane;
a plurality of slots provided in each of the plural waveguides;
at least one electromagnetic wave radiating window provided to face each slot; and
a vacuum vessel in which a plasma is generated by the electromagnetic wave radiated from the electro-magnetic wave radiating window,
wherein the plural waveguides are equal to each other in the length in the propagating direction of the electromagnetic wave, and the electromagnetic wave-distributing waveguide portion is provided on the plural waveguides in a manner to cross each of the waveguides at right angles.

4. A plasma processing apparatus, comprising:
at least one electromagnetic wave source for generating an electromagnetic wave;
an electromagnetic wave-distributing waveguide portion for distributing the electromagnetic wave generated from the electromagnetic wave source;
a plurality of waveguides each coupled with the electromagnetic wave-distributing waveguide portion, the waveguides being formed on the same plane;
a plurality of slots provided in each of the waveguides;
at least one electromagnetic wave radiating window provided to face each slot; and
a vacuum vessel in which a plasma is generated by the electromagnetic wave radiated from the electro-magnetic wave radiating window,
wherein the electromagnetic wave-distributing waveguide portion is provided on the plural waveguides and is coupled with each of the waveguides with a cross-guide coupler interposed therebetween.

5. A plasma processing apparatus, comprising:
at least one electromagnetic wave source for generating an electromagnetic wave;
an electromagnetic wave-distributing waveguide portion for distributing the electromagnetic wave generated from the electromagnetic wave source;
a plurality of waveguides each coupled with the electromagnetic wave-distributing waveguide portion, the waveguides being formed on the same plane;
a plurality of slots provided in each of the plural waveguide;
at least one electromagnetic wave radiating window provided to face each slot; and
a vacuum vessel in which a plasma is generated by the electromagnetic wave radiated from the electro-magnetic wave radiating window,
wherein the electromagnetic wave-distributing waveguide portion is provided on the plural waveguides, and an electromagnetic wave absorber is provided in an edge portion of each waveguide in a direction opposite to the propagating direction of the electromagnetic wave.

6. A plasma processing apparatus, comprising:
at least one electromagnetic wave source for generating an electromagnetic wave;
an electromagnetic wave-distributing waveguide portion for distributing the electromagnetic wave generated from the electromagnetic wave source;
a plurality of waveguides each coupled with the electromagnetic wave-distributing waveguide portion and provided in parallel on the same plane;
a plurality of slots provided in each of the plural waveguides;
at least one electromagnetic wave radiating window provided to face each slot; and
a vacuum vessel in which a plasma is generated by the electromagnetic wave radiated from the electro-magnetic wave radiating window,
wherein the electromagnetic wave-distributing waveguide portion is provided on the plural waveguides, and the distance between the inner surfaces of the adjacent waveguides is set shorter than the distance between the mutually facing inner surfaces of the waveguide, the inner surfaces extending in parallel.

7. The plasma processing apparatus according to claim 1, wherein the electromagnetic wave-distributing waveguide portion is coupled with each of the waveguides via a circular coupling hole formed in the overlapping portion between the electromagnetic wave-distributing waveguide portion and each of the waveguides.

8. The plasma processing apparatus according to claim 1, wherein the electromagnetic wave-distributing waveguide portion is coupled with the waveguides via oblong coupling holes inclined in alternately opposite directions relative to the extending direction of the electromagnetic wave-distributing waveguide portion.

9. The plasma processing apparatus according to claim 8, wherein the oblong coupling holes are inclined in alternately opposite directions by ±45° relative to the extending direction of the electromagnetic wave-distributing waveguide portion.

10. The plasma processing apparatus according to claim 1, wherein each of the waveguides is branched in two directions from the electromagnetic wave-distributing waveguide portion.

11. The plasma processing apparatus according to claim 1, wherein the electromagnetic wave is distributed from the electromagnetic wave-distributing waveguide portion into each of the waveguides such that the powers of the electromagnetic waves supplied into the individual waveguides are equal to each other.

12. The plasma processing apparatus according to claim 1, wherein the slots are uniformly distributed to permit the electromagnetic wave supplied into the vacuum vessel to cover uniformly the entire region of the substrate to which the plasma processing is applied.

13. The plasma processing apparatus according to claim 1, wherein:
the electromagnetic wave radiating windows are provided within the vacuum vessel such that each of the electromagnetic wave radiating windows is allowed to face at least two slots; and
the vacuum state is maintained in the clearance between the electromagnetic wave radiating windows and the vacuum vessel.

14. The plasma processing apparatus according to claim 1, wherein:
the vacuum vessel includes at least one beam having an inner surface;
the electromagnetic wave radiating windows are supported by the beams; and
the inner surface of the beam is covered with a dielectric material.

15. The plasma processing apparatus according to claim 1, wherein the adjacent electromagnetic wave sources emit electromagnetic waves having different frequencies.

16. The plasma processing apparatus according to claim 1, wherein the electromagnetic wave source emits an electromagnetic wave having a frequency of 2.45 GHz.

17. The plasma processing apparatus according to claim 1, wherein at least one plasma processing selected from the group consisting of a plasma oxidation, a plasma film formation, and a plasma etching is carried out within the vacuum vessel.

18. A plasma processing method, wherein a plasma oxidation and a plasma film formation are carried out under the vacuum state by using the plasma processing apparatus defined in claim 1, and the plasma oxidation and the plasma film formation are carried out consecutively without breaking the vacuum state within the vacuum vessel.

19. A plasma processing method, wherein at least one plasma processing selected from the group consisting of a plasma oxidation, a plasma film formation and a plasma etching is carried out by using the plasma processing apparatus defined in claim 1.
